(19) United States
(12) Patent Application Publication
(10) Pub. No.: US 2026/0352123 A1
(43) Pub. Date: Nov. 5, 2026

(54) DIRECTIONAL CASIMIR HARVESTER WITH ASYMMETRIC CAVITY GEOMETRY AND MODE ENGINEERING

(71) Applicant: Jonathan Washburn, Austin, TX (US)

(72) Inventor: Jonathan Washburn, Austin, TX (US)

(21) Appl. No.: 19/668,383

(22) Filed: May 5, 2026

Related U.S. Application Data
(60) Provisional application No. 63/800,223, filed on May 5, 2025.

(51) Int. Cl. H02N 2/00; H02J 50/00

(52) U.S. Cl. CPC H02N 2/002; H02J 50/001; H02N 2/0055

(57) ABSTRACT

A directional Casimir harvester generates electrical output from a directional Casimir pressure differential. An asymmetric Casimir cavity places a movable conductive element between opposed boundary structures at unequal gaps so that the narrower gap produces higher Casimir pressure than the wider gap, creating a net force that drives displacement converted to electrical output by a transducer. In a second family, a first plate patterned with an angularly selective metamaterial suppresses vacuum modes incident above a cutoff half-angle while an opposing reflective plate lacks the metamaterial, producing a net directional pressure differential. In preferred embodiments, d_wide/d_narrow=phi^Delta_r, where phi=(1+sqrt(5))/2 and Delta_r is an integer. Embodiments include MEMS implementations, patterned surfaces, planar arrays, stacked multilayers, eight-tick span selection, recognition-length filtering, and optional time-varying boundary modulation.

### CROSS-REFERENCE TO RELATED APPLICATIONS

This application claims the benefit of and priority to U.S. Provisional Patent Application 63/800,223, filed May 5, 2025, entitled “Directional Casimir and Zero-Point Energy Harvester,” the entire contents of which are incorporated herein by reference to the extent permitted by law.

### BACKGROUND

The present disclosure relates to energy harvesting from quantum vacuum fluctuations and, more particularly, to asymmetric Casimir cavity devices and methods that generate a directional Casimir pressure differential and convert displacement associated with that differential into electrical energy. The disclosure also relates, in certain preferred embodiments, to vacuum mode engineering, microelectromechanical systems, nanoscale electromechanical transduction, stacked harvester architectures, phi-scaled cavity design, eight-tick spectral selection, and recognition-length filtering.

The Casimir effect arises when conductive boundaries imposed in vacuum alter the allowed electromagnetic vacuum modes between those boundaries, thereby producing a measurable force. For parallel conductive surfaces separated by a gap distance d, the Casimir pressure magnitude scales according to:

P_Cas(d)=pi^2 hbar c/(240 d^4)

Accordingly, the pressure increases rapidly as the separation decreases. This strong inverse-fourth-power dependence makes sub-micron cavity geometry highly relevant to force magnitude, device scaling, and practical implementation.

Conventional Casimir structures, however, have generally been treated as symmetric force-generating configurations rather than as directional harvesting architectures. In a symmetric cavity, attractive forces may be present, but the geometry itself does not establish a directional pressure differential suitable for organized work extraction by a movable element. As a result, prior approaches have not adequately provided a clear cavity architecture in which unequal gap geometry itself produces a net directional force capable of driving a transducer.

In other directional architectures, a net directional Casimir pressure differential may be produced by anisotropic spectral admission rather than by unequal opposed gaps. In such embodiments, one cavity-facing plate is patterned with an angularly selective metamaterial configured to suppress vacuum electromagnetic modes incident above a selected angular cutoff while an opposing reflective plate admits the full spectrum. This one-sided mode suppression converts an otherwise isotropic Casimir interaction into a directional pressure differential that can drive a transducer and therefore provides an additional directional harvester family preserved by the present disclosure.

A further limitation in prior work is that cavity dimensions are often selected based primarily on fabrication convenience or generalized tuning considerations rather than on a deterministic geometric framework for cavity asymmetry and mode control. This leaves substantial ambiguity in cavity design, makes anti-design-around positioning more difficult, and weakens reproducibility where force differentials depend sensitively on nanoscale spacing. In addition, practical deployment faces challenges associated with small force magnitudes at useful gap sizes, transducer efficiency, array scaling, surface roughness, contamination, and fabrication tolerances.

In preferred RS-native embodiments, an additional limitation is that prior approaches do not constrain unequal-gap cavity geometry according to a deterministic phi-scaled spacing rule, do not select cavity spans from a finite allowed set associated with eight-tick periodicity, and do not apply a recognition-length threshold to suppress selected mode families. As a result, prior devices do not provide the same structured cavity family, repeatable gap ordering, or deterministic mode-selection architecture disclosed herein.

Accordingly, a need exists for a Casimir-based harvester architecture that preserves a clear core mechanism: a movable conductive element positioned between opposed boundaries at unequal gaps so that the smaller gap produces a larger Casimir pressure than the larger gap, thereby creating a net directional force that can be converted into electrical output. A further need exists, in preferred embodiments, for a structured cavity-design framework in which the unequal-gap relation is not arbitrary, but follows a deterministic phi-scaled spacing rule, and in which cavity spans and allowable modes are constrained by finite selection rules and threshold filters that support scalable and reproducible implementations.

### SUMMARY

The present disclosure provides a device, system, and method for directional harvesting of energy using an asymmetric Casimir cavity architecture in which a movable conductive element is disposed between opposed boundary structures at unequal gap separations. Because Casimir pressure increases as gap distance decreases according to an inverse-fourth-power relationship, the narrower-gap side produces a greater pressure than the wider-gap side, thereby creating a positive net directional force on the movable conductive element. That force-driven motion is converted into electrical output by an electromechanical transducer. In this manner, the disclosure preserves a clear directional-harvesting concept in which a directional Casimir pressure differential is created and used for organized work extraction and electrical energy generation. In one implementation family, the directional Casimir pressure differential is produced by unequal-gap cavity asymmetry. In another implementation family, the directional Casimir pressure differential is produced by anisotropic spectral admission associated with an angularly selective metamaterial.

In one aspect, the disclosure provides a method including providing an asymmetric Casimir cavity having a first gap and a second gap on opposite sides of a movable conductive element, the first gap being smaller than the second gap, permitting a directional Casimir pressure differential to act on the movable conductive element, displacing the movable conductive element in response to that pressure differential, and converting the resulting displacement into electrical output. In another aspect, the disclosure provides an apparatus or system including opposed boundary structures, a movable conductive element positioned between the boundary structures to define unequal gaps, and a transducer coupled to the movable conductive element so as to convert force-induced motion into usable electrical energy.

In another aspect, the disclosure provides a directional Casimir harvester in which a first plate is patterned with an angularly selective metamaterial and a second plate is reflective and lacks that metamaterial. In such embodiments, the metamaterial is configured so that vacuum modes incident above a selected angular cutoff alpha are suppressed while modes within an allowed angular cone remain admitted. The first plate therefore experiences a reduced effective vacuum-mode contribution relative to the second plate, thereby creating a directional Casimir pressure differential across the cavity. Mechanical deflection or strain associated with that directional pressure differential is converted into electrical output by a transducer coupled to at least one of the plates. In preferred implementations, the gap a between the plates is between 10 nm and 1 um.

In preferred embodiments, the unequal gaps are not arbitrarily selected, but instead satisfy a deterministic phi-scaled spacing rule. In such embodiments, the wider gap and the narrower gap satisfy:

d_wide/d_narrow=phi^Delta_r

where Delta_r is an integer rung separation and phi is the golden ratio. This spacing architecture defines a structured cavity family with repeatable gap ordering, deterministic scaling behavior, and strong anti-design-around value. In preferred implementations, adjacent phi-rungs or larger rung separations may be selected to control the magnitude of the directional pressure differential while preserving the same underlying asymmetric cavity mechanism.

In further preferred embodiments, the cavity is additionally configured for structured mode engineering. In such embodiments, cavity spans are selected from a finite allowed set associated with eight-tick periodicity, and a recognition-length threshold is used as a mode-filtering boundary. Modes shorter than the recognition length are suppressed, while longer modes are retained, thereby shaping the cavity mode population and reducing selected interior mode contributions relative to the exterior vacuum. In preferred RS-native embodiments, this structured mode engineering increases the interior/exterior mode-density differential and strengthens the disclosed harvesting architecture without altering the core identity of the invention as an unequal-gap directional Casimir harvester.

In preferred RS-native embodiments, the disclosed harvester architecture is further grounded in a structured vacuum framework in which vacuum fluctuations arise from discrete-time recognition dynamics. In such embodiments, time is treated as discrete at a fundamental scale tau_0, and vacuum fluctuations are treated as finite rather than divergent. The present materials further identify formal support corresponding to vacuum-energy positivity and eight-tick cancellation structure, thereby supplying an exact support layer for the structured harvesting embodiments.

In preferred analytical form, Casimir pressure magnitude is expressed as:

P_Cas(d)=pi^2 hbar c/(240 d^4),

where d is the operative cavity gap. In preferred deterministic spacing embodiments, gap values are parameterized by:

d_r=d_0*phi^r,

where d_0 is a base gap and r is an integer rung index. For an asymmetric cavity having d_narrow less than d_wide, the directional pressure differential is expressed as:

Delta_P=(pi^2 hbar c/240)*(1/d_narrow^4-1/d_wide^4),

and is positive whenever d_narrow is less than d_wide. The resulting net force may be expressed as Delta_F=Delta_P*A, where A is an effective active area. In preferred formulations, output power is expressed as:

P_out=eta*Delta_P*v_ext*A,

where eta is conversion efficiency and v_ext is extraction velocity. For arrayed embodiments, total output may scale according to:

P_array(N)=N×P_out,

where N is the number of active harvester cells.

In preferred device-level implementations, the asymmetric cavity is fabricated as a microelectromechanical system including a shuttle membrane or shuttle plate suspended between fixed boundary plates, a restoring structure coupled to the shuttle, and a transducer coupled to the shuttle or restoring structure. In certain preferred embodiments, the transducer is piezoelectric. In other embodiments, the transducer may be magnetostrictive, electromagnetic, or electrostatic. In further embodiments, one or more cavity-facing surfaces include phi-scaled corrugations or other engineered surface topography to increase selected mode coupling, improve roughness robustness, and provide additional spectral selectivity.

In some embodiments, multiple asymmetric Casimir harvester cells are arranged in a planar array on a common substrate, with outputs coupled in parallel for current addition. In other embodiments, multiple cells are vertically stacked in a multilayer architecture, with repeated narrow-gap and wide-gap regions and series electrical interconnection for voltage multiplication. These scalable implementations allow the disclosed harvester architecture to be expanded from single-cell devices to larger modules while preserving the same unequal-gap directional-force principle.

In certain optional embodiments, operation is supplemented by monitoring, calibration, and control logic. Such embodiments may include a reference cavity or coherence-monitoring element, a watchdog responsive to an imbalance threshold, an auto-calibration subsystem for maintaining a desired shuttle position or gap relationship, and power-conditioning circuitry for rectification, storage, and regulated output. These features may improve device management and output conditioning, but are not required to define the core asymmetric Casimir harvesting mechanism.

In certain additional embodiments, time-varying boundary modulation is used to generate a dynamic Casimir channel, and dynamic photons produced by the modulated boundary conditions may be captured, for example, by a photovoltaic element or another energy-conversion structure. In further embodiments, the asymmetric cavity is implemented as a continuously graded or spiral geometry, optionally with magnetostrictive transduction. These embodiments preserve the disclosed directional harvesting framework while extending it into additional advanced or future-facing implementations.

In certain design and verification embodiments, cavity geometry, gap relationships, directional force differential, and mode-selection criteria are evaluated computationally prior to fabrication. In some such embodiments, one or more aspects of the cavity architecture, including directional positivity, phi-gap relationships, array scaling, and eight-tick cancellation structure, are checked in a formal proof environment prior to layout generation, fabrication, or deployment. The present disclosure thus preserves not only a physical harvester architecture, but also a structured design framework for generating, screening, and validating implementations of that architecture.

The disclosure further preserves the distinction between the directional-harvesting concept and subordinate embodiments. In one principal embodiment family, the directional Casimir pressure differential is produced by an unequal-gap asymmetric Casimir harvester with transduction of force-driven motion into electrical output. In another preserved embodiment family, the directional Casimir pressure differential is produced by anisotropic spectral admission associated with an angularly selective metamaterial. The phi-scaled spacing rule is a principal deterministic preferred embodiment within the unequal-gap family. Eight-tick span selection and recognition-length filtering define preferred RS-native mode-engineered embodiment families. Array, stack, control, proof-assisted design, dynamic Casimir, spiral, and downstream product integrations are preserved as additional embodiment families without displacing the broader directional-harvesting concept.

In support of the disclosed architecture, the present materials further identify machine-verified results corresponding to Casimir-pressure positivity, Casimir scaling, phi-gap ratio and positivity, stronger narrow-side force, positive net directional differential, positive output-power formulation, linear array scaling, and eight-tick cancellation. These results provide formal support for preferred embodiments and fallback claim positions, while the disclosed inventive subject matter includes directional harvesting of Casimir-force asymmetry produced by unequal cavity gaps, anisotropic spectral admission produced by angularly selective metamaterials, and combinations thereof.

### BRIEF DESCRIPTION OF THE DRAWINGS

FIG. 1 is a cross-sectional view of a core asymmetric Casimir harvester cell showing unequal gaps on opposite sides of a movable conductive element, such that a narrower-gap side and a wider-gap side define a directional Casimir pressure differential.

FIG. 2 is a schematic force-and-pressure view illustrating stronger narrow-side Casimir pressure, weaker wide-side Casimir pressure, and the resulting net directional force acting on the movable conductive element.

FIG. 3 is a method flow diagram showing provision of the asymmetric cavity, generation of a directional pressure differential, displacement of the movable conductive element, and conversion to electrical output, with optional spectral-control branches.

FIG. 4 is a cross-sectional view of a MEMS piezoelectric embodiment showing a shuttle membrane, restoring structure, piezoelectric transducer, and unequal cavity gaps.

FIG. 5 is a top-plan view of a planar harvester array showing multiple asymmetric Casimir cells on a common substrate with shared electrical interconnection.

FIG. 6 is a cross-sectional view of a stacked multilayer harvester showing repeated narrow-gap and wide-gap regions, multiple movable elements, and series output combination.

FIG. 7 is a detailed view of an engineered cavity-surface embodiment showing periodic corrugations on one or more cavity surfaces and, in alternative embodiments, an angularly selective metamaterial configured to suppress selected vacuum modes above an angular cutoff.

FIG. 8 is a schematic mode-selection view showing eight-tick span selection, suppressed commensurate mode families, and retained mode families.

FIG. 9 is a recognition-length filtering view showing suppression of wavelengths shorter than a recognition-length threshold and quiet-band formation.

FIG. 10 is a system block diagram showing a harvester cell, transducer, rectifier, storage element, load, reference cavity or monitor, watchdog, and optional calibration and modulation blocks.

FIG. 11 is a schematic of a dynamic Casimir hybrid embodiment showing boundary modulation, dynamic photon generation, photovoltaic capture, and combined electrical output.

FIG. 12 is a plan or perspective view of a spiral or continuously graded gap embodiment with magnetostrictive transduction.

FIG. 13 is a design-and-verification workflow diagram showing input parameters, gap calculation, mode-selection logic, force and power estimation, layout generation, proof or verification steps, acceptance logic, and fabrication output.

### DETAILED DESCRIPTION

The present disclosure provides directional Casimir harvesters in which a directional Casimir pressure differential is created and converted into electrical output. In one implementation family, unequal cavity geometry creates the directional pressure differential by placing a movable conductive element between opposed boundary structures at different gap separations so that a narrower-gap side produces a greater Casimir pressure than a wider-gap side. In another implementation family, anisotropic spectral admission creates the directional pressure differential by providing a first cavity-facing plate with an angularly selective metamaterial that suppresses selected vacuum modes while an opposing reflective plate lacks that metamaterial and admits the full spectrum. In both families, the resulting directional force, deflection, or strain is coupled to a transducer and converted into electrical output.

The embodiments disclosed herein share a common inventive concept of generating a directional Casimir pressure differential by establishing asymmetric boundary conditions across a cavity-facing region and converting resulting force-driven motion or strain into electrical output.

Asymmetric boundary conditions may be realized by unequal opposed gaps, by anisotropic spectral admission including angular filtering, or by combinations thereof.

As used herein, an “asymmetric Casimir cavity” is a cavity architecture in which opposed cavity-facing structures define unequal separations relative to a movable conductive element. A “boundary surface” is a cavity-facing conductive or effectively conductive surface that participates in establishing vacuum boundary conditions. A “movable conductive element” is a force-receiving structure disposed between opposed boundary surfaces and capable of displacement, deflection, strain, or other motion in response to a Casimir pressure differential. In preferred embodiments, the movable conductive element is a shuttle plate or shuttle membrane.

A “narrow gap” is the smaller of two opposed cavity gaps, and a “wide gap” is the larger of the two opposed cavity gaps. A “net directional pressure differential” is the positive pressure difference that results when Casimir pressure on the narrow-gap side exceeds Casimir pressure on the wide-gap side. An “electromechanical transducer” is a structure that converts force-driven displacement or strain into an electrical output.

As used herein, “phi” means the golden ratio phi=(1+sqrt(5))/2, approximately 1.618.

As used herein, “Delta_r” means an integer rung separation (Delta_r is an integer and Delta_r is greater than or equal to 1) such that d_wide/d_narrow=phi^Delta_r.

As used herein, “alpha” means a cutoff half-angle measured from a surface normal of the metamaterial-patterned plate, and “theta” means an incidence angle of a mode measured from the same surface normal, such that modes with theta greater than alpha are suppressed.

As used herein, “recognition length” (lambda_rec) is a mode-filtering threshold length; in recognition-length-filtering embodiments, modes with wavelength lambda less than lambda_rec are suppressed relative to modes with wavelength lambda greater than or equal to lambda_rec within an operative cavity region.

An “angularly selective metamaterial” is a patterned cavity-facing structure configured to suppress vacuum electromagnetic modes incident above a selected angular cutoff while admitting at least a subset of modes within an allowed angular cone. A “recognition-cone metamaterial” is one example of such an angularly selective metamaterial. In embodiments using angularly selective metamaterial suppression, the directional pressure differential results from unequal spectral admission on opposite sides of the cavity rather than from unequal opposed gaps alone.

In preferred embodiments, the unequal-gap relation is not arbitrary, but instead follows a deterministic spacing architecture. In particular implementations, the gap ratio is defined by a phi-scaled relation of the form d_wide/d_narrow=phi^Delta_r, where Delta_r is an integer rung separation. In further preferred embodiments, cavity spans are selected from a finite allowed set associated with eight-tick periodicity, and a recognition-length threshold is used to suppress selected mode families. These preferred and further preferred embodiments strengthen the disclosed harvesting architecture, but do not alter the core identity of the invention as an unequal-gap directional Casimir harvester.

In additional embodiments preserved from the priority materials, the directional pressure differential is produced by one-sided angular filtering of vacuum modes. In such embodiments, a first plate is patterned with a recognition-cone metamaterial whose unit cells define an angular transmission function that suppresses vacuum modes incident above a selected cutoff angle alpha while leaving modes within the allowed cone substantially admitted. A second reflective plate spaced across a nanoscale gap from the first plate lacks that metamaterial. Because the first plate experiences only a reduced bright-cone contribution while the second plate experiences a larger effective vacuum-mode contribution, a net directional Casimir pressure differential is produced and may be converted to electrical output by a piezoelectric, electrostatic, thermophotovoltaic, or other transducer structure.

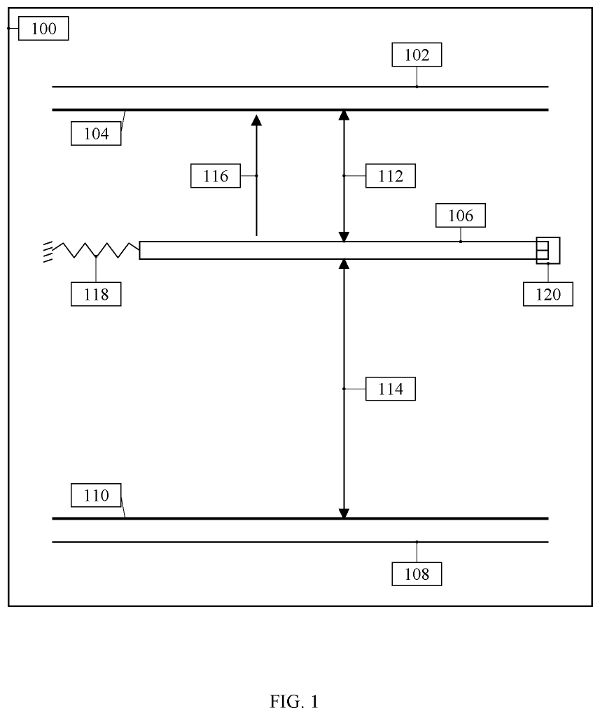

FIG. 1 depicts a core asymmetric Casimir harvester cell 100. The harvester cell 100 includes a first boundary plate 102 having a first conductive boundary surface 104, a shuttle plate 106, and a second boundary plate 108 having a second conductive boundary surface 110. The shuttle plate 106 is disposed between the first conductive boundary surface 104 and the second conductive boundary surface 110 so as to define a narrow gap 112 on one side of the shuttle plate 106 and a wide gap 114 on the other side of the shuttle plate 106. A net force direction 116 acts on the shuttle plate 106 as a result of the unequal-gap arrangement. In the illustrated embodiment, the shuttle plate 106 is mechanically associated with a restoring structure 118 and a transducer coupling or output path 120 configured to communicate force-driven displacement to an electrical conversion stage.

The arrangement shown in FIG. 1 is the load-bearing architecture of the present disclosure. The narrow gap 112 and the wide gap 114 are deliberately unequal, such that the cavity is asymmetric with respect to the shuttle plate 106. Because Casimir pressure increases strongly as gap distance decreases, the side associated with the narrow gap 112 produces a greater pressure magnitude on the shuttle plate 106 than the side associated with the wide gap 114. This creates a directional pressure differential across the shuttle plate 106 and produces the net force direction 116. The directional force is then used to drive displacement, strain, or other motion that may be harvested through the transducer coupling or output path 120.

In broad embodiments, the first conductive boundary surface 104, the shuttle plate 106, and the second conductive boundary surface 110 may be formed from conductive materials, conductive coatings, or structures that establish the desired vacuum boundary conditions over the operative cavity-facing regions. The first boundary plate 102 and the second boundary plate 108 may be rigid or effectively rigid relative to the intended displacement of the shuttle plate 106. The shuttle plate 106 may be supported by springs, beams, flexures, membranes, hinges, compliant suspensions, or other restoring structures 118 that permit controlled motion while maintaining the intended cavity geometry. The transducer coupling or output path 120 may couple the shuttle plate 106 directly or indirectly to a piezoelectric, magnetostrictive, electromagnetic, or electrostatic transducer.

In preferred embodiments, the unequal-gap relation shown in FIG. 1 is defined according to a deterministic spacing rule rather than arbitrary dimensional selection. In some embodiments, the wide gap 114 and the narrow gap 112 satisfy d_wide/d_narrow=phi^Delta_r. In certain implementations, Delta_r equals 1, such that the wide gap 114 is one phi-rung larger than the narrow gap 112. In other implementations, Delta_r is greater than 1 to increase the directional asymmetry. Regardless of whether the unequal-gap relation is expressed in a generic or phi-scaled form, the operative mechanism remains that the narrower-gap side produces a larger Casimir pressure than the wider-gap side.

In preferred phi-scaled embodiments, the unequal-gap ordering may be expressed quantitatively. For Delta_r=1, d_wide/d_narrow=phi, so the pressure ratio is (d_wide/d_narrow)^4=phi^4, approximately 6.854. Thus, the narrow-side force is approximately 6.85 times the wide-side force, and the resulting net force is approximately 0.854 times the narrow-side force. For Delta_r=2, d_wide/d_narrow=phi^2, so the pressure ratio is phi^8, approximately 46.98, and the resulting net force is approximately 0.979 times the narrow-side force. These exact orderings show that even modest rung separation can produce a strongly directional force architecture.

The cavity geometry of FIG. 1 may be implemented at a variety of scales, although nanoscale and sub-micron gap regimes are preferred where Casimir forces are stronger. The effective force may be increased through increased active area, reduced gap size, array replication, stacked architectures, increased transducer sensitivity, surface engineering, resonance tuning, or combinations thereof. In some embodiments, one or both of the first conductive boundary surface 104 and the second conductive boundary surface 110 may include engineered topography, including periodic corrugations or patterned features, to improve selected mode coupling, enhance structural repeatability, or reduce sensitivity to roughness.

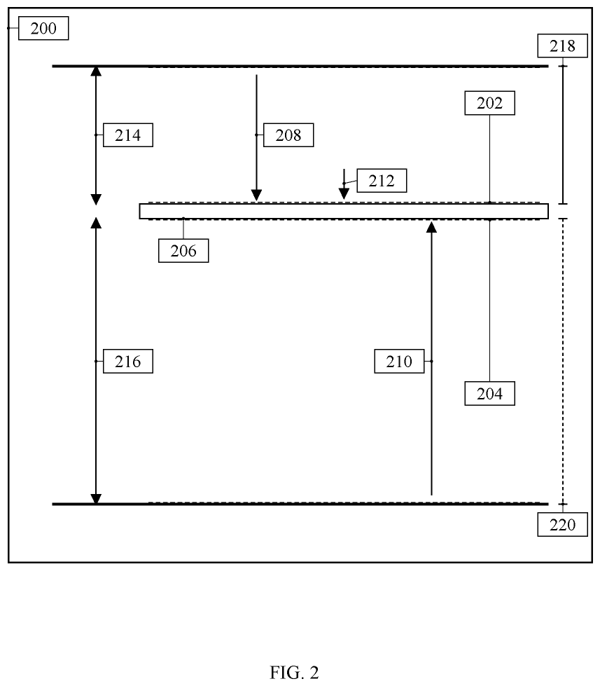

FIG. 2 depicts a force differential schematic 200 that illustrates the directional-force mechanism in greater detail. The force differential schematic 200 includes a narrow-side pressure region 202, a wide-side pressure region 204, a shuttle plate 206, a narrow-side force vector 208, a wide-side force vector 210, a net force vector 212, a narrow gap indicator 214, a wide gap indicator 216, a d^−4 scaling reference 218, and an optional phi-related gap ratio annotation 220. The narrow-side force vector 208 represents the pressure contribution associated with the narrow gap indicator 214, while the wide-side force vector 210 represents the pressure contribution associated with the wide gap indicator 216. Because the narrow gap indicator 214 corresponds to a smaller separation than the wide gap indicator 216, the narrow-side force vector 208 has a greater magnitude than the wide-side force vector 210, thereby yielding the net force vector 212.

In preferred analytical form, the Casimir pressure magnitude is expressed as:

P_Cas(d)=pi^2 hbar c/(240 d^4).

Accordingly, for an asymmetric cavity having d_narrow less than d_wide, the directional pressure differential may be expressed as:

Delta_P=(pi^2 hbar c/240)*(1/d_narrow^4−1/d_wide^4).

When d_narrow is less than d_wide, Delta_P is positive. The resulting net force may be expressed as Delta_F=Delta_P*A, where A is the effective active area over which the pressure differential acts. As a result, the directional-force architecture shown in FIG. 2 follows directly from the unequal-gap geometry and the inverse-fourth-power Casimir scaling relation.

The d^−4 scaling reference 218 shown in FIG. 2 is strategically important because it explains why even moderate gap asymmetry can produce a substantial directional force differential. A reduction in gap size does not produce a merely linear or quadratic increase in pressure, but rather a fourth-power increase. Thus, a cavity family having ordered and reproducible unequal gaps can provide a robust mechanism for directional force generation. In preferred embodiments using the optional phi-related gap ratio annotation 220, the gap ordering is further constrained by a deterministic phi-scaled relation, which provides a structured design family rather than an arbitrary set of unequal-gap devices.

The force-differential architecture of FIG. 2 also supports computational and formal validation workflows. In design-stage embodiments, candidate cavity geometries may be screened by verifying that the narrow gap indicator 214 is smaller than the wide gap indicator 216 and that the resulting Delta_P is positive. In preferred RS-native embodiments, further validation may include verification of phi-gap ordering, finite allowed-set span selection, recognition-length threshold compliance, or formal checking of directional positivity in a proof environment. In this manner, the present disclosure supports not only physical implementations, but also structured geometry-generation and validation workflows tied to the same directional-force mechanism.

The results associated with the FIG. 1 and FIG. 2 architecture are further supported, in preferred embodiments, by machine-verified formal results identified in the present materials, including positivity of Casimir pressure, Casimir scaling, phi-gap ratio and positivity, stronger narrow-side force, and positive net directional differential. These formal results do not replace physical implementation detail, but strengthen the disclosure by providing an exact support layer for the directional-force architecture and its deterministic preferred embodiment families.

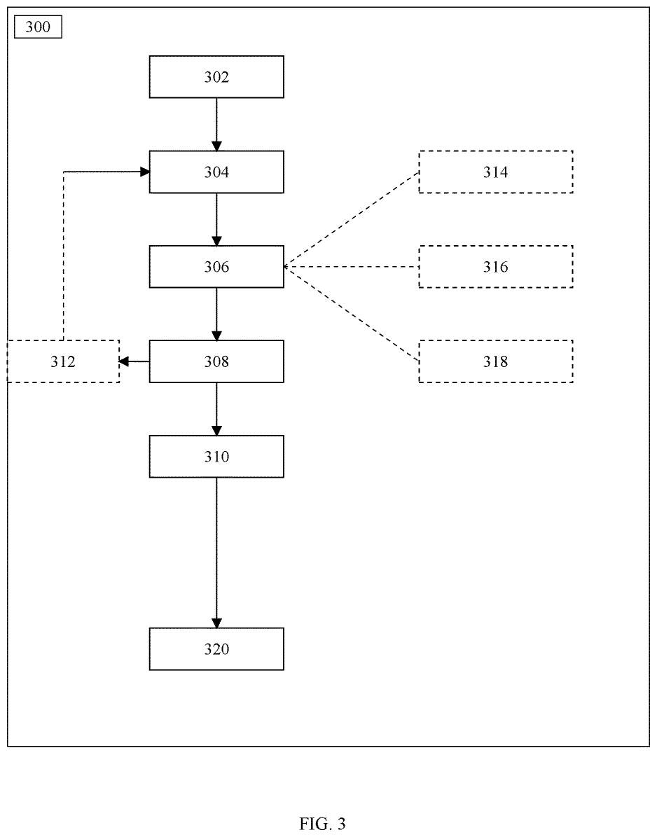

FIG. 3 depicts a method workflow 300 for directional Casimir harvesting. The method workflow 300 includes a step 302 of providing an asymmetric cavity, a step 304 of establishing an unequal-gap relationship, a step 306 of generating a directional pressure differential, a step 308 of displacing a movable element, a step 310 of converting displacement to electrical output, an optional step 312 of resetting or restoring the movable element, an optional branch 314 for applying surface patterning, an optional branch 316 for applying eight-tick span selection, an optional branch 318 for applying recognition-length filtering, and an output step 320 for conditioning, storing, or using the generated electrical output.

In the step 302 of providing an asymmetric cavity, a cavity architecture is established in which a movable conductive element is positioned between opposed boundary structures. In broad embodiments, the cavity may be formed by fixed plates and a shuttle plate, fixed surfaces and a movable membrane, or any other configuration that defines opposed cavity-facing conductive regions and permits force-driven motion of an intermediate movable element. In preferred embodiments, the movable element is a shuttle membrane or shuttle plate suspended relative to first and second boundary plates.

In the step 304 of establishing an unequal-gap relationship, the movable conductive element is positioned so as to define a first gap on one side and a second gap on the other side, with the first gap being smaller than the second gap. In broad embodiments, this unequal-gap relationship may be established by physical fabrication, assembly tolerance control, spacer geometry, support-structure placement, bonded-layer thickness selection, or combinations thereof. In preferred embodiments, the unequal-gap relationship is established according to a deterministic spacing rule in which d_wide/d_narrow=phi^Delta_r. In certain implementations, the narrower gap and wider gap are selected from a predefined cavity family corresponding to rung-separated phi-scaled values.

In the step 306 of generating a directional pressure differential, the unequal cavity geometry permits the narrower-gap side to exert a larger Casimir pressure magnitude than the wider-gap side, thereby generating a positive Delta_P across the movable conductive element. This step may occur passively by virtue of the cavity geometry itself, without requiring a symmetric-force-balancing configuration. In design-stage embodiments, the step 306 may additionally include calculating or verifying Delta_P from the selected gap values and active area. In preferred validation embodiments, cavity geometries that do not produce a positive Delta_P are rejected prior to fabrication or operation.

In the step 308 of displacing the movable element, the directional pressure differential causes the movable conductive element to translate, deflect, strain, flex, or otherwise move in a force-receiving direction. Depending on implementation, the displacement may be approximately linear, rotational, membrane-like, spring-constrained, resonant, or quasi-static. In preferred embodiments, the displacement is limited by restoring structures, mechanical stops, spring constants, resonance constraints, or pull-in avoidance criteria so that the cavity remains within a defined operating range.

In the step 310 of converting displacement to electrical output, motion of the movable conductive element is coupled to a transducer. In preferred embodiments, the transducer is piezoelectric and produces a voltage responsive to strain associated with the displacement. In other embodiments, the transducer may be magnetostrictive, electromagnetic, or electrostatic. The electrical output may initially be alternating, pulsed, transient, or charge-accumulating, depending on the transduction mechanism and operating mode.

The optional step 312 of resetting or restoring the movable element may be performed by a spring, beam, flexure, electrostatic return force, magnetic return force, mechanical bias, or other restoring mechanism. In preferred operating embodiments, the load stroke is driven by the directional Casimir pressure differential and the reset stroke is governed by the restoring architecture. In further preferred RS-native embodiments, the disclosed operating rationale treats the unequal-gap geometry and associated mode-density differences as supporting a net extraction cycle. The reset architecture may be passive or actively controlled, and may be tuned to a desired resonance or frequency band.

In preferred operating-cycle embodiments, the displacement stage functions as a load stroke during which the directional Casimir force performs work on the movable conductive element, and the restoring stage functions as a reset stroke during which the movable conductive element is returned toward a starting configuration. In the disclosed operating rationale, the reset energy is less than the extraction energy because vacuum mode density differs on the two sides of the asymmetric cavity, such that the unequal-gap geometry supports a net energy flow from the vacuum-field structure to the transduction pathway. This operating rationale is preserved as part of the disclosed invention story and preferred extraction architecture.

Energy accounting and verification protocol. In embodiments configured for net electrical power generation, device operation is verified by measuring (i) electrical energy delivered to a storage element and/or load over a defined time window and (ii) any externally supplied electrical, mechanical, optical, magnetic, or electromagnetic energy used for reset, biasing, modulation, control, sensing, monitoring, calibration, or conditioning over the same time window. In one verification protocol, the device is operated for N cycles (for example, N is greater than or equal to 10^6 during characterization) while recording shuttle displacement x(t), transducer voltage v(t), transducer current i(t), and any externally supplied input-channel signals u_k(t). Electrical output energy is computed as E_out=int_{t0}^{t1} v(t)*i(t) dt delivered to a calibrated load or storage element. Total externally supplied input energy is computed as E_in =sum over k of int_{t0}^{t1} p_k(t) dt, where p_k(t) is the power delivered by external input channel k.

A design or build is accepted as exhibiting net generation over the test window when (E_out E_in) is greater than or equal to E_margin, where E_margin is a predefined positive margin selected to exceed measurement uncertainty (for example, E_margin is greater than or equal to 5*U_total, where U_total is the combined energy-measurement uncertainty bound for E_out and E_in over the same window).

In embodiments using a restoring structure, restoring action may be passive (for example, spring return) or may be actively biased. Where any active bias is used, its contribution is included in E_in.

In embodiments using modulation (dynamic-channel embodiments), modulation-drive energy is included in E_in, and net generation is evaluated on the combined static-channel and dynamic-channel electrical output.

The optional branch 314 permits application of surface patterning to one or more cavity-facing surfaces. In such embodiments, periodic corrugations or other patterned features may be introduced to increase selected mode coupling, improve roughness robustness, or contribute additional spectral selectivity. The optional branch 316 permits application of eight-tick span selection, in which cavity spans are selected from a finite allowed set associated with eight-tick periodicity. The optional branch 318 permits application of recognition-length filtering, in which modes shorter than a recognition-length threshold are suppressed while longer modes are retained. These optional branches preserve structured embodiment families without altering the core method steps 302 through 310.

The output step 320 may include rectifying the transducer output, storing the output in a capacitor, battery, or other storage element, combining outputs from multiple cells, regulating voltage, delivering current to a load, or routing power to a downstream device. In some embodiments, the output step 320 includes combining outputs from multiple arrayed harvester cells in parallel for current addition or from multiple stacked harvester cells in series for voltage multiplication. In design-and-verification embodiments, the output step 320 may further include generation of layout data, force estimates, proof results, or fabrication-ready design packages associated with the same underlying cavity architecture.

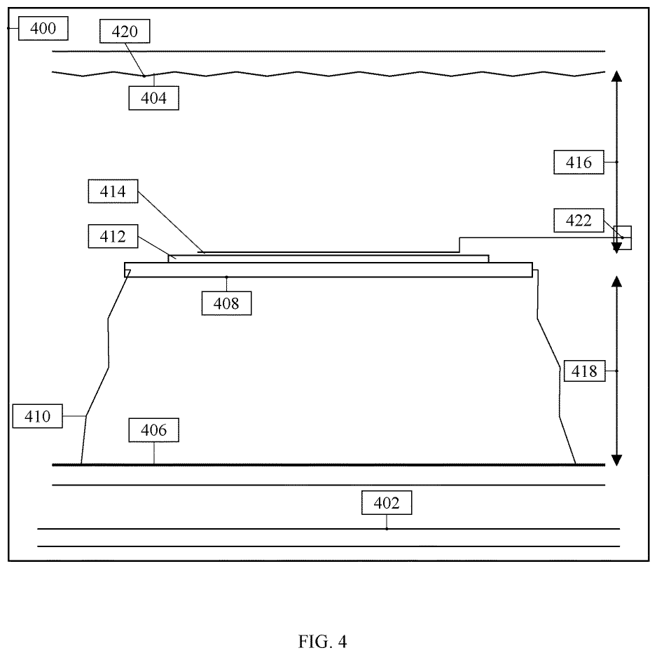

FIG. 4 depicts a MEMS harvester 400 including a substrate 402, a first fixed boundary plate 404, a second fixed boundary plate 406, a shuttle membrane 408, folded-beam supports 410, a piezoelectric layer 412, an electrode 414, a narrow gap 416, a wide gap 418, a surface corrugation region 420, and an output trace 422. In the illustrated embodiment, the shuttle membrane 408 is suspended relative to the fixed boundary plates 404, 406 so as to define the narrow gap 416 on one side and the wide gap 418 on the opposite side. The folded-beam supports 410 provide mechanical compliance and restoring behavior, while the piezoelectric layer 412 and electrode 414 convert force-driven strain into electrical output delivered through the output trace 422.

The MEMS harvester 400 is a preferred concrete implementation of the broader asymmetric Casimir harvesting architecture. The substrate 402 may be silicon, silicon-on-insulator, glass, ceramic, or another microfabrication-compatible substrate. The fixed boundary plates 404, 406 may be formed as rigid or effectively rigid conductive structures, and may include conductive coatings such as gold or other suitable cavity-facing conductive materials. The shuttle membrane 408 may be silicon nitride, silicon, metal-coated membrane material, multilayer thin-film material, or another compliant conductive or coated structure capable of participating in the disclosed cavity geometry.

In preferred embodiments, the folded-beam supports 410 are configured to permit controlled displacement of the shuttle membrane 408 while maintaining repeatable spacing relative to the fixed boundary plates 404, 406. The spring constant of the folded-beam supports 410 may be selected in view of desired displacement range, resonance frequency, pull-in avoidance, fatigue tolerance, and transduction sensitivity. In certain embodiments, the folded-beam supports 410 also serve as strain-concentrating regions for the piezoelectric layer 412. In other embodiments, the transduction region may be positioned elsewhere on or adjacent to the shuttle membrane 408.

The piezoelectric layer 412 may be aluminum nitride, lead zirconate titanate, or another piezoelectric material suitable for thin-film deposition. The electrode 414 may include one or more conductive traces, plates, or patterned electrode regions configured to collect voltage or charge associated with deformation of the piezoelectric layer 412. In preferred embodiments, the output trace 422 routes the generated electrical signal toward rectification, storage, measurement, conditioning, or external use circuitry. Although the embodiment of FIG. 4 shows piezoelectric conversion, the same cavity geometry may alternatively be coupled to magnetostrictive, electromagnetic, or electrostatic conversion structures.

The narrow gap 416 and the wide gap 418 may be established by lithographic definition, spacer thickness control, sacrificial-layer removal, bonded-wafer spacing, membrane geometry, support geometry, or combinations thereof. In preferred embodiments, the narrow gap 416 and wide gap 418 are selected in a phi-related ratio, for example by defining the wide gap 418 as a phi-rung multiple of the narrow gap 416. In one representative embodiment disclosed in the present materials, the narrow gap is approximately 50 nm and the wide gap is approximately 80.9 nm for Delta_r=1. Other gap values and other rung separations may be used while preserving the same asymmetric directional-force principle.

The surface corrugation region 420 represents an optional engineered-surface embodiment in which one or more cavity-facing surfaces are patterned to provide additional mode selectivity, enhanced coupling at selected spatial frequencies, and reduced sensitivity to uncontrolled roughness. In some embodiments, the corrugation period is itself phi-scaled. In other embodiments, the patterned region may be applied to only one of the cavity-facing surfaces, to both fixed boundary plates 404, 406, to the shuttle membrane 408, or to combinations thereof.

The MEMS harvester 400 may be fabricated using a process flow including substrate preparation, thin-film deposition, lithographic patterning, etching, release of the shuttle membrane 408, conductive coating deposition, transducer deposition, electrode formation, and cavity closure or bonding. In one preferred fabrication path, an SOI wafer is used, the cavity geometry is patterned lithographically, the shuttle membrane 408 is released by etching, conductive surfaces are formed by sputtering or deposition, the piezoelectric layer 412 is deposited, and the cavity is completed by bonding or assembling an opposing boundary structure to define the narrow gap 416 and wide gap 418. These fabrication details provide a concrete make-and-use disclosure for the preferred MEMS embodiment.

The MEMS harvester 400 may be operated in a quasi-static mode, in a resonant mode, or in another mechanically tuned mode. In resonant embodiments, the support stiffness, shuttle mass, cavity dimensions, and transducer characteristics may be selected to favor operation near a desired resonance, thereby increasing displacement amplitude or energy-conversion efficiency. In practical embodiments, mechanical displacement may be limited to maintain cavity integrity, prevent pull-in, preserve repeatable operation, and avoid undesired contact between the shuttle membrane 408 and the boundary structures.

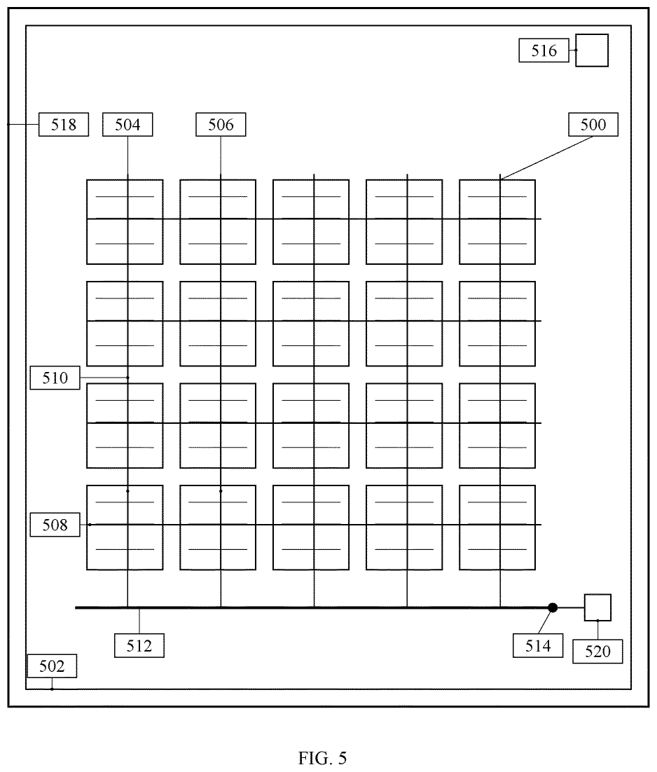

FIG. 5 depicts a planar array 500 including a substrate 502, a first harvester cell 504, a second harvester cell 506, row interconnects 508, column interconnects 510, a parallel output bus 512, a current-combining node 514, a control or bond pad 516, a perimeter frame 518, and a module output terminal 520. Although only representative harvester cells 504, 506 are specifically labeled, the planar array 500 may include a large number of asymmetric Casimir harvester cells distributed across the substrate 502 in a repeated layout. Each such cell may be implemented according to the core architecture of FIG. 1 and, in preferred embodiments, according to the MEMS architecture of FIG. 4.

The planar array 500 supports scaling of the disclosed harvester architecture through area replication while preserving the same unequal-gap directional-force mechanism at the cell level. Each cell within the planar array 500 may include a narrow-gap side and a wide-gap side arranged to produce a directional pressure differential on a corresponding movable conductive element. The outputs of the cells may then be electrically combined. In the illustrated embodiment, row interconnects 508 and column interconnects 510 route the outputs of multiple cells toward the parallel output bus 512 and the current-combining node 514, thereby increasing total available current at the module output terminal 520.

In some embodiments, the substrate 502 is a semiconductor substrate, glass substrate, ceramic substrate, interposer, flexible substrate, or other carrier suitable for fabrication and routing of multiple harvester cells. The perimeter frame 518 may provide mechanical stiffness, environmental enclosure support, bonding support, packaging registration, contamination control, or combinations thereof. The control or bond pad 516 may be used for external electrical connection, testing, trimming, calibration, or integration with downstream circuitry.

The planar array 500 may be laid out according to a uniform pitch, variable pitch, tiled pitch, or density-optimized pattern. In preferred embodiments, cell pitch and routing density are selected to preserve fabrication tolerance, maintain cavity integrity, and optimize electrical collection efficiency. In some embodiments, cells are arranged so that their directional-force axes are aligned in a common orientation. In other embodiments, subsets of cells may be mirrored, rotated, or grouped according to packaging, routing, or transduction requirements, while still preserving the individual unequal-gap harvesting architecture.

In preferred large-area embodiments, the planar array 500 is used to scale the output of single-cell architectures that may otherwise produce only small amounts of power individually. Because each cell preserves the same directional-force principle, array-level output may scale with the number of active cells, subject to packaging, routing, conditioning, and fabrication constraints. In some embodiments, outputs are combined in parallel to increase current. In other embodiments, subsets of cells may be grouped into series-connected blocks, parallel-connected blocks, or hybrid network topologies.

The planar array 500 may further support shared conditioning, monitoring, or control architecture. In some embodiments, the parallel output bus 512 is coupled to shared rectification or storage circuitry. In some embodiments, the control or bond pad 516 is used to access test structures, reference cavities, or calibration nodes associated with one or more cells. In still further embodiments, the planar array 500 is integrated monolithically or heterogeneously with downstream electronics, sensing elements, control logic, or communication circuitry so as to form a self-powered or partially self-powered module. Such integrations remain downstream uses of the disclosed harvester architecture and do not alter the core inventive mechanism.

The planar array architecture of FIG. 5 also supports design-stage screening and validation. Candidate cell counts, pitches, routing patterns, and bus configurations may be evaluated in view of total active area, target output, allowable current density, acceptable voltage drop, mechanical isolation, roughness tolerance, and fabrication constraints. In preferred proof-assisted design embodiments, array-level configurations may additionally be checked for preservation of positive per-cell directional force and for expected scaling behavior consistent with the disclosed array architecture.

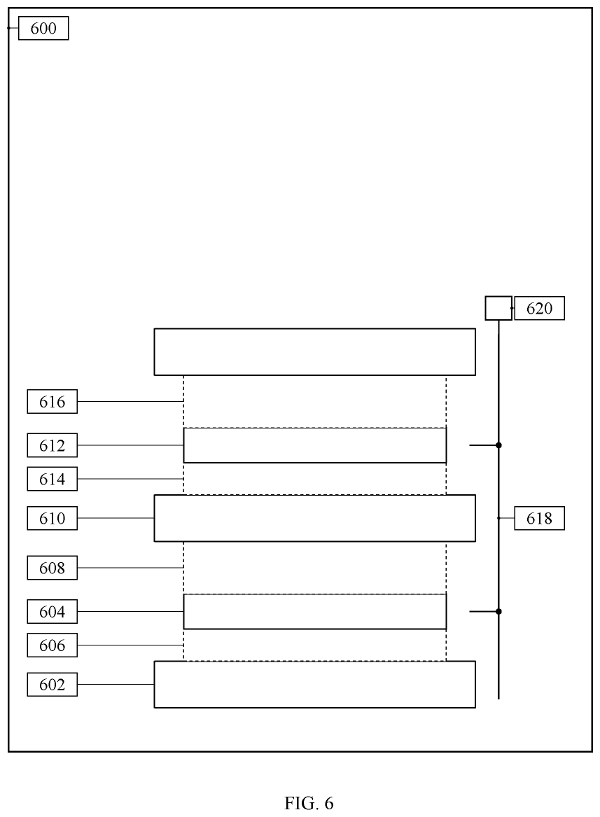

FIG. 6 depicts a stacked multilayer harvester 600 including a first boundary layer 602, a first shuttle layer 604, a first narrow gap 606, a first wide gap 608, a second boundary layer 610, a second shuttle layer 612, a second narrow gap 614, a second wide gap 616, a series interconnect 618, and a stack output node 620. The illustrated embodiment shows a vertically repeated architecture in which multiple asymmetric cavity stages are arranged through the thickness of the device rather than solely across a planar substrate. Each shuttle layer is positioned between adjacent boundary layers so as to define a narrower gap on one side and a wider gap on the other side, thereby preserving the same unequal-gap directional-force mechanism described for the single-cell embodiments.

The stacked multilayer harvester 600 is a preferred scaling embodiment in which multiple asymmetric harvester cells are integrated vertically to increase total output per unit footprint. In the illustrated portion of the stack, the first shuttle layer 604 is disposed between the first boundary layer 602 and the second boundary layer 610 so as to define the first narrow gap 606 and the first wide gap 608. Similarly, the second shuttle layer 612 is disposed relative to adjacent boundary structures so as to define the second narrow gap 614 and the second wide gap 616. Each shuttle layer is therefore acted upon by a directional Casimir pressure differential resulting from the corresponding unequal-gap geometry.

In preferred embodiments, the stacked multilayer harvester 600 is configured so that the directional-force orientation of the successive shuttle layers is aligned constructively. That is, the narrow-gap side of each active stage is arranged so that the resulting force-driven motion contributes coherently to a chosen electrical output configuration. In certain implementations, this constructive alignment supports series combination of electrical outputs for voltage multiplication. In other implementations, subsets of stacked stages may be combined in parallel for current addition, or in mixed series-parallel arrangements depending on target output characteristics.

The series interconnect 618 represents a preferred electrical coupling architecture for stacked output aggregation. In embodiments where each shuttle layer is coupled to a piezoelectric or other transducer structure, the series interconnect 618 may combine stage-level voltages so that the stack output node 620 presents a multiplied output voltage relative to a single stage. In one representative disclosed arrangement, repeated narrow-gap and wide-gap pairs are vertically stacked and electrically combined to provide increased voltage suitable for logic, sensing, or conditioning circuitry. The stack output node 620 may be coupled to rectification, storage, regulation, or downstream loads.

The stacked multilayer harvester 600 may be fabricated using repeated conductive layers, sacrificial layers, spacer layers, membrane layers, bonded wafers, deposited thin films, or combinations thereof. In some embodiments, alternating metal and sacrificial layers are formed and then selectively removed to release one or more shuttle layers. In other embodiments, atomic layer deposition, wafer bonding, precision deposition, or layer-by-layer assembly is used to define the repeated cavity geometry. In preferred embodiments, nanoscale layer-thickness control is used to preserve the intended narrow-gap and wide-gap ordering through the stack.

In certain embodiments, the first narrow gap 606 and the first wide gap 608, and likewise the second narrow gap 614 and the second wide gap 616, may be selected according to a phi-scaled spacing rule. In this manner, each vertically repeated cavity stage may belong to the same deterministic cavity family as the single-cell embodiments. In some implementations, identical gap pairs are repeated through the stack. In other implementations, the stack may include mixed rung separations, graded rung separations, or stage-specific spacing values selected to optimize voltage, current, frequency response, fabrication tolerance, or mechanical stability while preserving the unequal-gap directional-force principle.

The stacked multilayer architecture may additionally be combined with the optional structured mode-engineering families disclosed herein. For example, individual stages or groups of stages may employ engineered surface topography, eight-tick-compatible spans, or recognition-length threshold filtering. Such features may be repeated identically through the stack or varied between stages. In one class of embodiments, the stack is designed so that all stages share a common mode-engineering rule set. In another class of embodiments, different vertical stages are tuned for different spectral or transduction characteristics. These variations remain subordinate to the underlying stacked unequal-gap architecture.

The stacked multilayer harvester 600 is particularly useful where footprint is constrained but greater voltage output is desired. By repeating the directional harvester cell vertically, the device may increase output per unit plan-view area while retaining the same fundamental cavity mechanism. The stacked arrangement may also be used in combination with planar arrays, such that multiple vertical stacks are distributed laterally across a common substrate or module. In this manner, two-dimensional and three-dimensional scaling approaches may be combined.

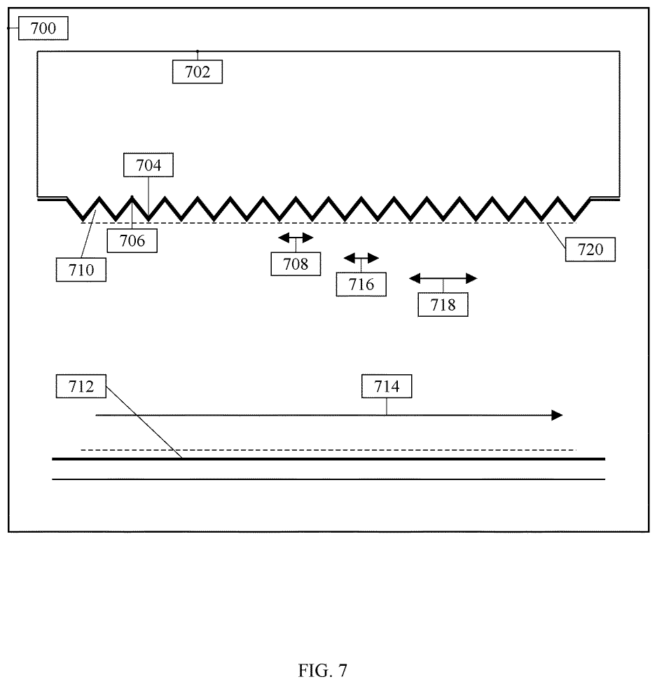

FIG. 7 depicts a patterned boundary embodiment 700 including a boundary body 702, corrugation crests 704, corrugation troughs 706, a corrugation period 708, a conductive coating 710, an opposing shuttle surface 712, a pattern direction 714, a first representative period 716, a second representative period 718, and a patterned interaction region 720. The illustrated embodiment shows an engineered cavity-facing surface in which periodic or quasi-periodic topography is introduced on the boundary body 702 and coated or otherwise configured to provide the conductive coating 710 facing the opposing shuttle surface 712. The patterned interaction region 720 defines the portion of the cavity in which the engineered surface profile influences mode behavior and force generation.

The patterned boundary embodiment 700 provides a preferred engineered-surface family in which one or more cavity-facing surfaces are intentionally structured rather than left nominally flat. The corrugation crests 704 and corrugation troughs 706 define a repeating surface profile having the corrugation period 708 measured along the pattern direction 714. In preferred embodiments, the corrugation period 708 is selected according to a phi-related rule, such that representative periods 716, 718 correspond to a phi-scaled family of spatial periodicities. In such embodiments, the patterned boundary embodiment 700 becomes part of the deterministic phi-scaled cavity-design architecture disclosed herein.

In one class of patterned-boundary embodiments, the boundary body 702 is patterned as an angularly selective metamaterial rather than as a purely periodic corrugated surface. In such embodiments, the patterned interaction region 720 is configured so that vacuum electromagnetic modes incident above a selected angular cutoff alpha are suppressed while modes within an allowed angular cone remain substantially admitted. This architecture may be implemented as a recognition-cone metamaterial and provides a directional harvester family in which anisotropic spectral admission, rather than unequal opposed gaps alone, produces the directional Casimir pressure differential.

In one representative implementation preserved from the priority materials, the metamaterial unit cells comprise cylindrical scatterers arranged on a lattice over the boundary body 702 and coated or otherwise configured to define the conductive coating 710. In more specific implementations, the scatterers have a radius of approximately 0.25a and a height of approximately 2a, where a is the operative cavity gap, and are arranged on a square lattice having a pitch of approximately (phi/pi)*a. In representative embodiments, the metamaterial is configured to provide a stop band for modes incident at angles greater than alpha with a finite angular roll-off.

In such metamaterial embodiments, the cavity may be formed by the patterned first boundary and an opposing reflective plate separated by a nanoscale gap a. The patterned first boundary experiences a reduced effective vacuum-mode contribution corresponding to an admitted bright-cone component, while the opposing reflective boundary experiences the fuller isotropic contribution. In one analytical expression, the bright-cone contribution may be represented as P_bright(a)=P_iso(a)*cos(alpha), so that the directional pressure differential may be represented as Delta_P(a)=P_iso(a)−P_bright(a)=P_iso(a)*(1−cos(alpha)). Mechanical deflection produced by that directional pressure differential may be converted into electrical output by a piezoelectric cantilever, an electrostatic structure, a thermophotovoltaic structure, or another transducer coupled to at least one cavity plate.

Metamaterial embodiments of this class may be fabricated by lithographically patterning the boundary body 702, etching or otherwise forming the metamaterial features, depositing conductive material including gold or another cavity-facing conductive layer, defining a sacrificial spacer corresponding to the gap a, bonding an opposing plate, and removing the sacrificial material to establish the cavity. In representative implementations, the gap a is between 10 nm and 1 um, and in further representative implementations the gap a is between 20 nm and 50 nm. A plurality of such metamaterial-based harvesters may be arranged in an array or stacked architecture to increase combined output.

The conductive coating 710 may be a metal film, conductive layer, conductive composite, or other cavity-facing conductive structure suitable for establishing vacuum boundary conditions over the engineered topography. The boundary body 702 may be a rigid substrate, deposited structural layer, semiconductor body, ceramic body, or another microfabrication-compatible support. The opposing shuttle surface 712 may be part of a movable shuttle plate, membrane, flexure-supported structure, or other movable conductive element disposed across a corresponding narrow or wide gap. In some embodiments, the surface patterning is present only on the fixed boundary side. In other embodiments, complementary or corresponding patterning may also be present on the movable side.

The patterned boundary embodiment 700 may serve multiple functions. First, the engineered topography may increase effective coupling at selected spatial frequencies and thereby alter the cavity's vacuum mode response. Second, the patterned interaction region 720 may reduce sensitivity to uncontrolled roughness by causing selected engineered spatial features to dominate the cavity interaction rather than random surface irregularities. Third, the periodic or phi-scaled spatial structure may contribute an additional filtering mechanism that complements unequal-gap asymmetry, eight-tick span selection, or recognition-length threshold filtering. In preferred embodiments, the patterned boundary architecture therefore supports both force enhancement and mode-engineering functions.

In some embodiments, the corrugation period 708 is selected to correspond to a single preferred spatial periodicity. In other embodiments, multiple representative periods such as the first representative period 716 and the second representative period 718 may be used in different device families, in different regions of a single device, or on different cavity-facing surfaces. In certain implementations, the patterned boundary embodiment 700 includes a set of phi-related periods that define a structured family of surfaces corresponding to different rung values. In other implementations, the period may be selected in view of fabrication resolution, cavity size, desired mode coupling, or roughness tolerance.

The engineered topography of FIG. 7 may be fabricated by lithography, nanoimprint, etching, deposition-patterning, focused-beam writing, mechanical texturing, wafer-scale replication, or other suitable surface-formation methods. In MEMS embodiments, the patterned boundary may be integrated into the same process flow used to form the cavity-defining structures. In larger-scale embodiments, the patterned boundary may be introduced as a post-fabrication or pre-bonding treatment. In certain embodiments, patterning is confined to a localized active region. In other embodiments, substantially the entire cavity-facing area may be patterned.

The patterned boundary embodiment 700 supports a distinct fallback claim family around engineered cavity-facing topography. Even where the broadest independent claim does not require topography, the present disclosure preserves patterned surfaces as a preferred implementation that may improve selected mode coupling, increase repeatability, and reduce roughness-driven uncertainty while still operating within the same unequal-gap directional Casimir harvesting framework.

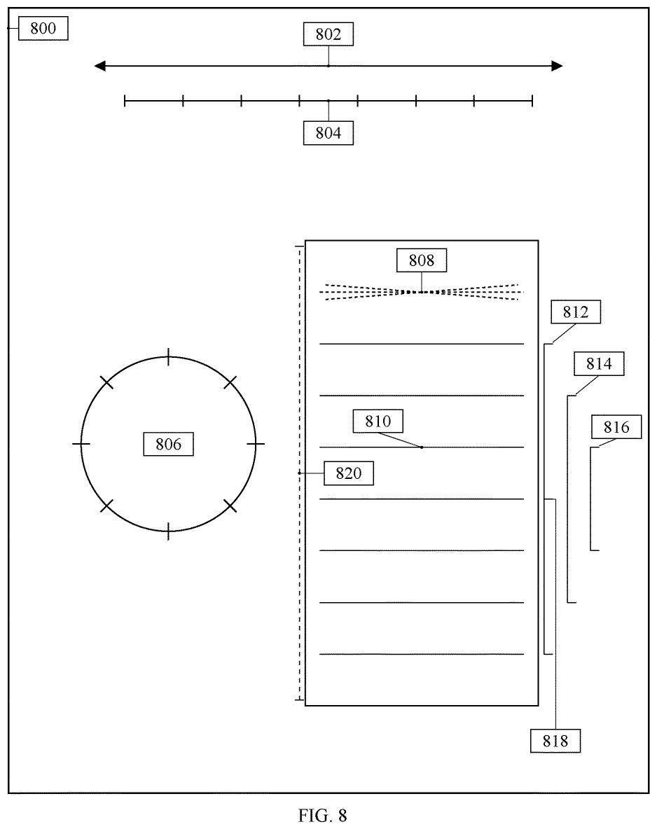

FIG. 8 depicts an eight-tick mode-engineering schematic 800 including a cavity span parameter 802, a finite allowed span set 804, an eight-tick reference 806, a suppressed commensurate mode family 808, a retained mode family 810, a first conjugate pair 812, a second conjugate pair 814, a third conjugate pair 816, a singleton mode 818, and a reduced interior mode-density region 820. The illustrated schematic represents a preferred RS-native spectral-control architecture in which cavity span selection is not arbitrary, but instead is constrained by a finite allowed set 804 associated with eight-tick periodicity.

In preferred embodiments, the eight-tick reference 806 corresponds to an eight-phase periodicity characterized by the cancellation identity:
sum from k=0 to 7 of exp(i k pi/4)=0

This identity supports a mode-selection framework in which selected commensurate mode families are suppressed. In the embodiment of FIG. 8, the suppressed commensurate mode family 808 represents those mode contributions that are disfavored or canceled under the eight-tick span-selection rule, while the retained mode family 810 represents those mode contributions that remain available in the cavity. The reduced interior mode-density region 820 schematically represents the resulting reduction in selected interior mode density relative to an unconstrained cavity.

The cavity span parameter 802 may represent a cavity dimension, span, extent, or equivalent geometric quantity used to determine whether a candidate cavity belongs to the finite allowed span set 804. In preferred embodiments, candidate cavity spans are screened against the finite allowed span set 804 and spans outside that set are rejected for the eight-tick embodiment family. In this manner, span selection becomes a deterministic rule-governed operation rather than unconstrained optimization. This structured span-selection architecture is an important differentiator of the preferred RS-native embodiment family.

The first conjugate pair 812, second conjugate pair 814, and third conjugate pair 816 represent preferred retained mode groupings corresponding to non-DC mode families that may remain after commensurate-mode suppression. The singleton mode 818 represents an additional retained mode family that is not paired in the same manner. In the present disclosure, these groupings provide a deterministic way to describe how the cavity mode population is structured under the eight-tick mode-engineering architecture. Although FIG. 8 is schematic, it supports the disclosed arrangement in which mode families are organized, suppressed, or retained according to a finite-rule periodicity framework rather than arbitrary tuning alone.

In preferred eight-tick embodiments, the retained non-DC modes are organized into explicit mode families. A first conjugate pair corresponds to modes 1 and 7. A second conjugate pair corresponds to modes 2 and 6. A third conjugate pair corresponds to modes 3 and 5. A singleton mode corresponds to mode 4. In this arrangement, commensurate eight-tick structure governs which mode families are suppressed and which remain available, thereby providing deterministic control over cavity mode behavior rather than unconstrained spectral tuning.

In some embodiments, the finite allowed span set 804 is used alone. In other embodiments, eight-tick span selection is combined with phi-scaled gap ordering, surface patterning, recognition-length filtering, or combinations thereof. For example, a cavity may first be defined by an unequal-gap phi-related geometry and then further constrained so that one or more cavity spans fall within the finite allowed span set 804. In still other embodiments, a designer or automated tool may evaluate a set of candidate cavity spans, reject spans outside the finite allowed set 804, and retain only those spans that satisfy the eight-tick selection rule while also producing a positive directional pressure differential.

The mode-engineering schematic of FIG. 8 is not limited to any single transduction mechanism or packaging style. The finite allowed span set 804 and associated mode-family structure may be applied to single harvester cells, MEMS cells, planar arrays, stacked multilayer devices, or other embodiments disclosed herein. In some embodiments, all cells of an array or all stages of a stack share a common span-selection rule. In other embodiments, different cells or groups of cells may use different spans drawn from the same finite allowed set 804. Such implementations remain within the same structured eight-tick mode-engineering family.

The eight-tick mode-engineering schematic 800 also supports computational, design-stage, and proof-assisted implementations. In design workflows, the cavity span parameter 802 may be computed from candidate layout geometry and compared to the finite allowed span set 804. In proof-assisted embodiments, the underlying eight-tick cancellation identity and related structured-mode properties may be checked in a formal proof environment. In this way, FIG. 8 supports not only a physical cavity family, but also a deterministic selection and validation architecture that can be used before fabrication.

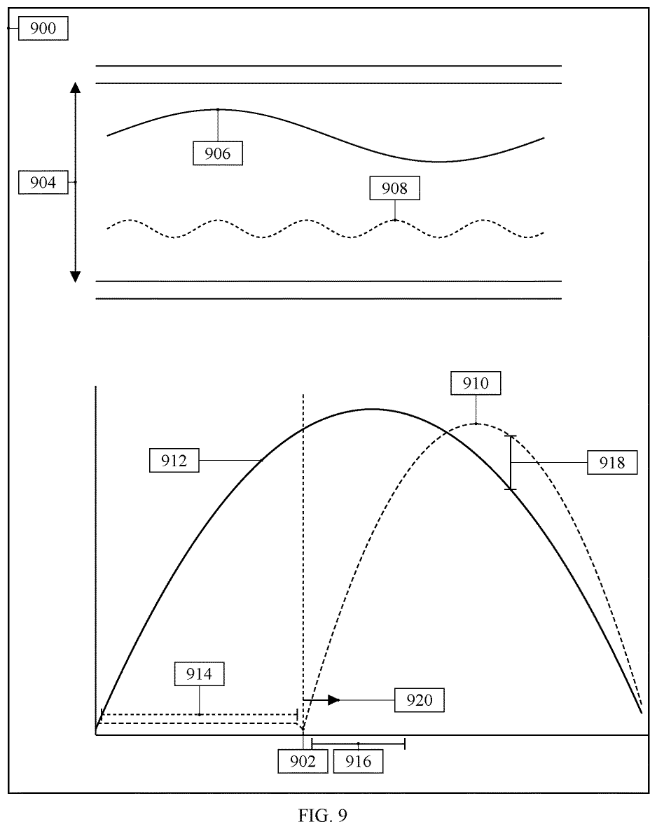

FIG. 9 depicts a recognition-length filtering architecture 900 including a recognition-length threshold 902, a cavity gap dimension 904, an allowed long-wavelength mode 906, a suppressed short-wavelength mode 908, an interior spectrum 910, an exterior spectrum 912, a quiet band 914, an operating band 916, an energy-density differential 918, and a filter decision boundary 920. The illustrated embodiment represents a preferred RS-native filtering family in which a recognition length is used as a threshold for determining whether a mode is admitted to or suppressed from the cavity region associated with the harvester architecture.

In preferred embodiments, the recognition-length threshold 902 is treated as a mode-filtering boundary such that wavelengths shorter than the recognition length are suppressed and wavelengths equal to or greater than the recognition length are allowed. Thus, the allowed long-wavelength mode 906 represents a mode family admitted under the threshold rule, while the suppressed short-wavelength mode 908 represents a mode family excluded under that same rule. In one preferred analytical expression identified in the present disclosure, the number of allowed modes is given by:

N_allowed=floor(2d/lambda_rec)

where d is the operative cavity gap and lambda_rec is the recognition length. In this manner, mode admission is tied to a threshold relation rather than unconstrained tuning.

The cavity gap dimension 904 may correspond to the narrow gap, the wide gap, an effective cavity span, or another geometry-dependent length used to evaluate admissible mode families in the specific embodiment. In some embodiments, the recognition-length threshold 902 is evaluated relative to a single cavity dimension. In other embodiments, separate threshold analyses may be applied to more than one cavity dimension, to multiple cells in an array, or to multiple stages in a stack. Regardless of implementation, the filtering rule preserves the same essential structure: shorter modes are excluded and longer modes are retained according to a threshold comparison.

The interior spectrum 910 represents the mode population that remains inside the cavity after application of the threshold rule, while the exterior spectrum 912 represents the surrounding or unrestricted vacuum mode population. Because the threshold rule suppresses selected interior mode families, the interior spectrum 910 may differ from the exterior spectrum 912 over one or more frequency or wavelength regions. The quiet band 914 schematically represents a region in which admissible interior mode density is reduced. In preferred embodiments, the quiet band 914 overlaps or is selected relative to the operating band 916 of the harvester architecture so that the filtering rule contributes to a reduced interior mode population over a range relevant to device operation.

The energy-density differential 918 represents the resulting difference between the interior spectral density and the exterior spectral density after application of the recognition-length threshold. In preferred embodiments, the threshold rule is used to support a positive interior/exterior energy-density differential over one or more spectral regions. In some implementations, the recognition-length filtering architecture is used alone. In other implementations, it is combined with unequal-gap asymmetry, phi-scaled spacing, eight-tick span selection, patterned cavity surfaces, or combinations thereof. Thus, the recognition-length filtering architecture 900 may act as a stand-alone preferred embodiment family or as a cooperative filter layer within a broader structured harvester design.

In preferred embodiments, the threshold-filtered cavity may be characterized by an energy-density differential:

Delta_rho=rho_exterior−rho_interior,

where rho_exterior corresponds to an unrestricted or less restricted surrounding mode density and rho_interior corresponds to the filtered interior cavity mode density. When the threshold rule and associated cavity selection produce Delta_rho greater than zero over an operative spectral region, the resulting differential supports the disclosed directional harvesting architecture. Quiet-band formation may therefore be used as a deterministic design indicator in recognition-length-filtered embodiments.

The filter decision boundary 920 represents the threshold comparison applied in design, screening, or operation. In a design-stage embodiment, candidate modes or candidate cavity geometries may be evaluated against the filter decision boundary 920, and designs that fail to provide the desired threshold relation may be rejected. In automated design embodiments, the recognition-length threshold 902 may be used as an input to a geometry generator or acceptance evaluator. In proof-assisted embodiments, recognition-length conditions and associated mode-admission structure may be checked before layout generation or fabrication. In all such implementations, FIG. 9 preserves a deterministic filtering rule rather than a merely qualitative spectral preference.

The recognition-length filtering architecture 900 may be implemented in single cells, MEMS devices, planar arrays, stacked multilayer devices, or other embodiments disclosed herein. In some embodiments, a common recognition-length threshold 902 is applied across all cells or stages. In other embodiments, different device regions may be assigned different recognition-length thresholds or different cavity dimensions while still operating within the same threshold-based filtering framework. The disclosure therefore preserves a broad family of threshold-filtered embodiments without requiring that every embodiment use the same exact cavity size or packaging arrangement.

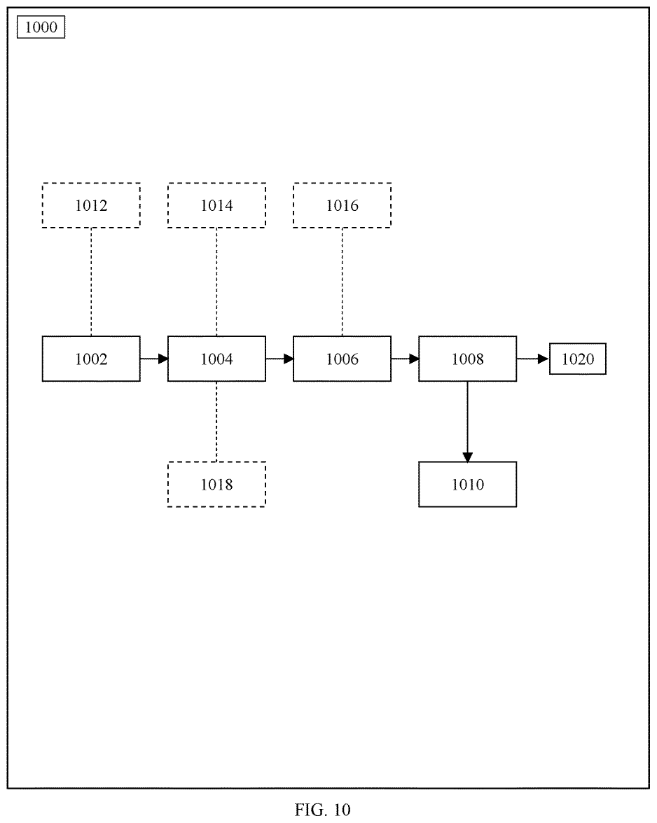

FIG. 10 depicts a harvester system 1000 including an asymmetric cavity cell 1002, a transducer 1004, a rectifier 1006, a storage element 1008, a load 1010, a reference cavity or coherence monitor 1012, a watchdog circuit 1014, an auto-calibration module 1016, an optional modulation driver 1018, and a system output terminal 1020. The illustrated system provides a preferred integration architecture in which the core unequal-gap harvester cell is coupled to electrical conditioning, optional monitoring and control, and optional advanced operating functions.

The asymmetric cavity cell 1002 may correspond to any of the harvester-cell embodiments described herein, including a single unequal-gap cavity, a MEMS shuttle implementation, a patterned-surface embodiment, a mode-engineered embodiment, or an array or stacked stage treated as a system input block. The asymmetric cavity cell 1002 provides force-driven motion responsive to a directional Casimir pressure differential. The transducer 1004 is mechanically or electromechanically coupled to the cavity cell 1002 so as to convert the resulting motion, strain, or displacement into electrical output. In preferred embodiments, the transducer 1004 is piezoelectric. In other embodiments, the transducer 1004 may be magnetostrictive, electromagnetic, electrostatic, or another suitable conversion structure.

The rectifier 1006 receives the output of the transducer 1004 and converts that output into a conditioned form suitable for charging or supplying the storage element 1008 or the load 1010. In embodiments where the transducer output is alternating, pulsed, or otherwise non-DC, the rectifier 1006 may include diode structures, switched-capacitor structures, active rectification structures, or other conditioning circuitry. In preferred embodiments, the storage element 1008 is a capacitor, battery, supercapacitor, reservoir node, or another energy-storage structure that accumulates electrical output generated by the harvester system 1000. The load 1010 may be a sensor, logic block, communication block, controller, actuator, external device, or another powered subsystem. The system output terminal 1020 provides an external or module-level interface for conditioned power delivery.

The reference cavity or coherence monitor 1012 is an optional monitoring structure that may be used in preferred RS-native embodiments to observe a coherence-related value, an imbalance-related value, a reference spectral condition, or another control parameter associated with the operating state of the harvester system 1000. In some embodiments, the reference cavity or coherence monitor 1012 is physically adjacent to the asymmetric cavity cell 1002. In other embodiments, it is integrated into a common module or coupled through a measurement pathway. The reference cavity or coherence monitor 1012 is not required for the core harvester mechanism, but provides a structured control and monitoring family for advanced implementations.

The watchdog circuit 1014 is an optional control block that may respond when a monitored quantity exceeds or falls below a threshold. In preferred embodiments, the watchdog circuit 1014 is configured to disconnect, gate, limit, or otherwise modify operation of the harvester system 1000 when an imbalance threshold is exceeded. The threshold may correspond to a coherence-related value, a control-state value, a reference-cavity-derived value, or another system-operating parameter. In some implementations, the watchdog circuit 1014 acts on the transducer 1004, the rectifier 1006, the storage element 1008, or the optional modulation driver 1018. In other implementations, the watchdog circuit 1014 may simply provide a monitoring or disable output.

The auto-calibration module 1016 is another optional control block that may be used to maintain or restore a desired operating configuration of the harvester system 1000. In certain embodiments, the auto-calibration module 1016 adjusts the shuttle rest position, support bias, gap relation, control reference, or another parameter so that the asymmetric cavity cell 1002 remains within a desired operating range. In some embodiments, the auto-calibration module 1016 cooperates with the reference cavity or coherence monitor 1012 and the watchdog circuit 1014. In other embodiments, the auto-calibration module 1016 operates independently, for example by tracking output level, force level, displacement level, or resonant response.

In further preferred RS-native embodiments, the harvester system 1000 may operate according to a ledger-neutral extraction protocol. In such embodiments, a local vacuum state or cavity state is monitored through the reference cavity or coherence monitor 1012, energy is extracted in controlled increments, and the watchdog circuit 1014 is configured to respond if an imbalance-related value exceeds a threshold. In preferred implementations, the protocol preserves a zero-net-imbalance operating target while allowing the system to continue operating when the monitored state remains within an acceptable range. In this manner, FIG. 10 preserves not only electrical conditioning and calibration, but also an advanced RS-native governance family tied to controlled extraction and threshold-verified operation.

The optional modulation driver 1018 is included to preserve advanced embodiments in which time-varying modulation is applied to one or more cavity-related structures. In some embodiments, the optional modulation driver 1018 is inactive and the harvester system 1000 operates purely as a static unequal-gap directional harvester. In other embodiments, the optional modulation driver 1018 drives a boundary-condition change, a mechanical modulation, an electrical modulation, or another excitation associated with a dynamic or hybrid mode of operation. Accordingly, FIG. 10 supports both static core embodiments and advanced modulated embodiments without altering the identity of the core invention.

The harvester system 1000 may be implemented as a single-cell module, an array-connected module, a stacked multilayer module, an on-chip integrated power source, or another package-level embodiment. In some implementations, the rectifier 1006, storage element 1008, and load 1010 are shared among multiple harvester cells. In other implementations, each cell or group of cells may have a dedicated conditioning path. The system block architecture of FIG. 10 therefore supports a broad family of packaging and integration variants while preserving the same underlying unequal-gap directional-force kernel.

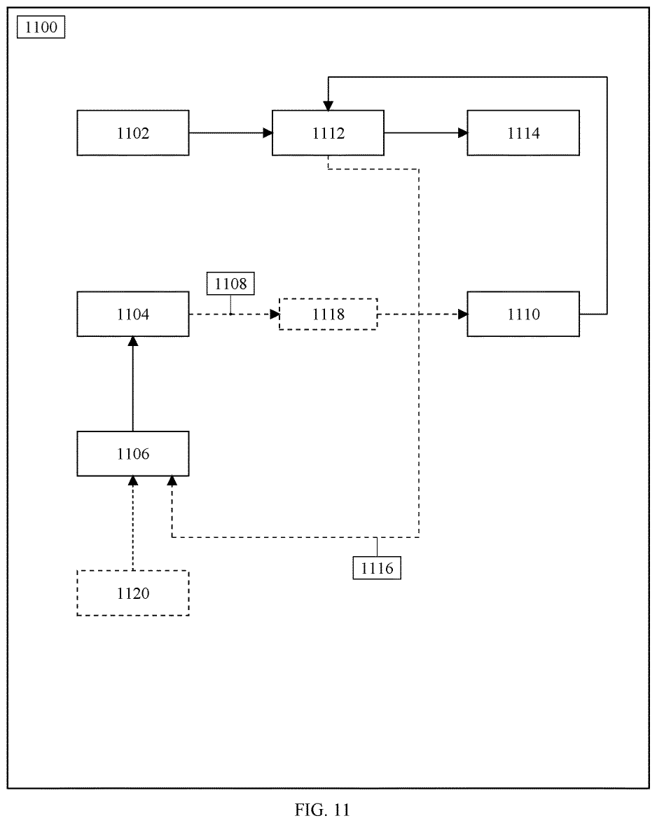

FIG. 11 depicts a dynamic hybrid harvester 1100 including a static asymmetric cavity 1102, a modulated boundary element 1104, a modulation source 1106, a dynamic photon path 1108, a photovoltaic capture element 1110, an electrical combiner 1112, a conditioned output 1114, a feedback path 1116, a threshold controller 1118, and a harmonic-selection block 1120. The dynamic hybrid harvester 1100 is an advanced embodiment that preserves the static unequal-gap harvester architecture while further introducing a dynamic Casimir channel associated with time-varying boundary conditions.

The static asymmetric cavity 1102 corresponds to the core directional harvester architecture disclosed herein and may include unequal opposed gaps defining a positive directional force differential on a movable conductive element. In preferred embodiments, the static asymmetric cavity 1102 produces a first electrical contribution through the same kind of transduction pathway described elsewhere in this disclosure. The modulated boundary element 1104 is an additional structure associated with time-varying cavity or boundary behavior. In some embodiments, the modulated boundary element 1104 is a cavity wall, plate, membrane, or conductive boundary whose electromagnetic or geometric state is modulated. In other embodiments, the modulation may be applied indirectly through a coupled boundary condition.

The modulation source 1106 provides the time-varying drive used to actuate the modulated boundary element 1104. In some embodiments, the modulation source 1106 is an electrical drive source. In other embodiments, it may be optical, mechanical, magnetic, or otherwise coupled to the modulated boundary element 1104. The harmonic-selection block 1120 may be used, in preferred advanced embodiments, to select or constrain modulation frequencies, including frequencies related to the cavity geometry, the narrow-gap dimension, the wide-gap dimension, phi-related harmonics, or other chosen dynamic criteria. In this manner, the dynamic hybrid harvester 1100 preserves a structured advanced embodiment rather than an unconstrained modulation concept.

The dynamic photon path 1108 represents the generation and routing of dynamic Casimir photons or photon pairs associated with the time-varying cavity or boundary conditions. The photovoltaic capture element 1110 is configured to receive at least a portion of the photons associated with the dynamic photon path 1108 and convert that received photon energy into electrical output. Thus, in preferred advanced embodiments, the dynamic hybrid harvester 1100 includes two harvesting channels: a static directional-force channel associated with the static asymmetric cavity 1102 and a dynamic photon-conversion channel associated with the modulated boundary element 1104 and photovoltaic capture element 1110.

In preferred advanced embodiments, the dynamic channel is configured as an augmentation of the static harvesting baseline rather than as a replacement for the asymmetric cavity core. The modulation source 1106 may therefore be selected so that the dynamic photon path 1108 contributes an additional electrical component above the static channel output, with the fraction of that contribution depending on modulation amplitude, harmonic selection, and cavity configuration. This preserves the disclosed hybrid architecture as a two-channel harvesting family built on top of the unequal-gap directional-force kernel.

The electrical combiner 1112 combines electrical output from the static channel and the dynamic channel. In some embodiments, the electrical combiner 1112 adds current contributions. In other embodiments, it combines voltages, routes channel outputs through separate conditioning paths, or selects between modes of operation. The conditioned output 1114 may be rectified, stored, regulated, or delivered to a downstream load. In some embodiments, the conditioned output 1114 is provided to a storage element or system output terminal of the kind described with respect to FIG. 10.

The feedback path 1116 and threshold controller 1118 preserve additional advanced-control embodiments. In certain implementations, a portion of harvested output is fed back through the feedback path 1116 to support operation of the modulation source 1106. In some embodiments, the threshold controller 1118 is configured to enable, disable, limit, or modify the dynamic channel depending on whether one or more operating conditions are satisfied. Such conditions may include output level, modulation amplitude, cavity condition, force level, spectral condition, or another advanced operating parameter. In some embodiments, the threshold controller 1118 ensures that the dynamic channel is engaged only when a desired operating threshold is met.

The dynamic hybrid harvester 1100 should be understood as an advanced or prophetic embodiment family that extends, rather than replaces, the static unequal-gap harvester core. In preferred drafting posture, FIG. 11 is used to preserve continuation-worthy subject matter and dependent-claim support while keeping the broadest independent claim centered on the static asymmetric cavity architecture. Nonetheless, the present disclosure preserves the dynamic hybrid embodiment with sufficient structural detail to support future claim families directed to modulation-assisted harvesting, dynamic photon capture, hybrid static-dynamic operation, or feedback-controlled advanced implementations.

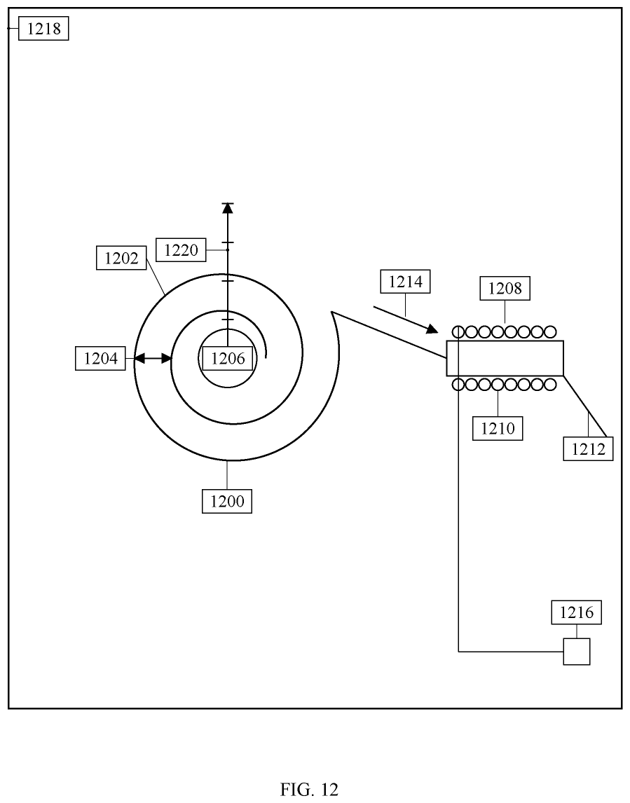

FIG. 12 depicts a spiral harvester 1200 including a spiral boundary 1202, a graded gap 1204, an inner boundary or opposing surface 1206, a magnetostrictive core 1208, a pickup coil 1210, a support structure 1212, a force or strain direction 1214, an output lead 1216, a substrate or housing 1218, and a radial coordinate indicator 1220. The illustrated embodiment preserves an advanced alternative geometry in which the unequal-gap relation is implemented through a continuously varying or spiral cavity architecture rather than through a purely planar parallel-plate arrangement. The spiral boundary 1202 and the inner boundary or opposing surface 1206 cooperate to define the graded gap 1204, which varies as a function of radial position indicated by the radial coordinate indicator 1220.

In the embodiment of FIG. 12, the graded gap 1204 provides a continuously varying asymmetric cavity relation along the extent of the spiral boundary 1202. In some implementations, the graded gap 1204 decreases in one radial direction and increases in the opposite radial direction, thereby creating a geometry in which different local regions exhibit different Casimir gap values. In preferred advanced embodiments, the graded gap 1204 is selected so that at least a portion of the spiral architecture preserves a directional pressure differential analogous to the directional-force principle described for the discrete unequal-gap embodiments. Thus, the FIG. 12 embodiment preserves the same broad harvesting concept while expressing the unequal-gap architecture in a continuously graded form.

The magnetostrictive core 1208 is mechanically associated with the spiral boundary 1202, the inner boundary or opposing surface 1206, or another force-receiving portion of the structure such that force-induced strain or displacement is transmitted to the magnetostrictive core 1208. The pickup coil 1210 is positioned relative to the magnetostrictive core 1208 so that strain-induced flux changes are converted into electrical output. The output lead 1216 communicates this electrical output to conditioning, storage, monitoring, or downstream use circuitry. In this manner, FIG. 12 preserves a transduction family that differs from the piezoelectric MEMS embodiment while remaining within the overall directional harvester disclosure.

The support structure 1212 may include a frame, compliant mount, suspension, anchor, spiral arm support, or another structure configured to maintain the intended cavity relation while permitting the desired force or strain direction 1214. In some embodiments, the support structure 1212 is configured to reduce stress concentration relative to discrete planar embodiments. In other embodiments, the support structure 1212 is configured to preserve a desired spiral pitch, radial stability, or transduction alignment. The substrate or housing 1218 may provide environmental protection, packaging support, mechanical registration, magnetic-path support, or another structural function.

In preferred advanced embodiments, the spiral boundary 1202 follows a golden or phi-related spiral geometry, and the graded gap 1204 is selected according to a continuously varying phi-related relation. In other embodiments, the graded gap 1204 may be selected according to a non-spiral continuous taper, piecewise gradient, stepped gradient, or other spatially varying geometry while still preserving the broad concept of a directional harvester based on unequal cavity conditions. In some implementations, the spiral embodiment may additionally incorporate patterned surfaces, span-selection constraints, recognition-length filtering, or hybrid dynamic features.

The FIG. 12 embodiment should be treated as an alternative or advanced embodiment family rather than as the load-bearing core of the present application. It is useful for preserving broader future flexibility and continuation support directed to graded-gap, non-planar, spiral, or magnetostrictive implementations. At the same time, its inclusion in the present specification helps demonstrate that the underlying inventive idea is not limited to one particular rectangular or planar cavity format, but may be realized in multiple geometries that preserve directional asymmetry and transduction of force-driven motion into electrical output.

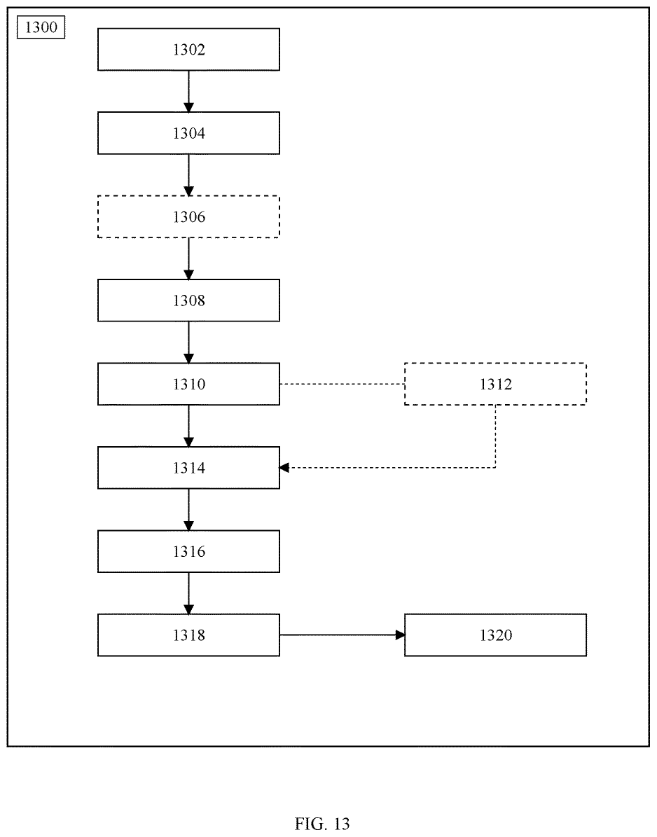

FIG. 13 depicts a design workflow 1300 including a design input set 1302, a gap-calculation module 1304, a mode-selection module 1306, a force and power estimator 1308, a layout generator 1310, a proof or verification engine 1312, an acceptance-criteria evaluator 1314, a fabrication package output 1316, a fabricated-device handoff 1318, and a validation report 1320. The design workflow 1300 preserves a design-stage and proof-assisted embodiment family in which the disclosed harvester architecture is computationally generated, screened, and optionally formally verified before fabrication or deployment.

The design input set 1302 may include one or more target outputs, gap bounds, available materials, transducer type selections, fabrication constraints, area limits, stage-count limits, surface-patterning options, whether phi-scaled spacing is enabled, whether eight-tick span selection is enabled, whether recognition-length filtering is enabled, and other design parameters relevant to a chosen harvester implementation. In broad embodiments, the design input set 1302 need only include enough information to generate an asymmetric unequal-gap cavity that produces a positive directional pressure differential. In more structured embodiments, the design input set 1302 may also include deterministic spacing requirements, threshold values, or rule-based selection criteria associated with the preferred RS-native embodiment families.

The gap-calculation module 1304 receives the design input set 1302 and determines one or more candidate narrow-gap and wide-gap values. In broad embodiments, the gap-calculation module 1304 determines candidate geometries satisfying d_narrow less than d_wide. In preferred embodiments, the gap-calculation module 1304 determines gap values according to a phi-related rule, for example by assigning a base gap and one or more rung-separated related gaps satisfying d_wide/d_narrow=phi^Delta_r. In some embodiments, the gap-calculation module 1304 also determines effective active area, stage count, support geometry, or stack spacing.

The mode-selection module 1306 is used in preferred structured embodiments to apply additional cavity-design rules. In some implementations, the mode-selection module 1306 evaluates whether candidate cavity spans fall within a finite allowed set associated with eight-tick periodicity. In some implementations, the mode-selection module 1306 applies a recognition-length threshold to classify modes as allowed or suppressed. In still other embodiments, the mode-selection module 1306 accounts for patterned surfaces, span families, stage-specific rules, or other spectral-control conditions. The mode-selection module 1306 may be inactive in broad embodiments that do not require these preferred RS-native constraints.

The force and power estimator 1308 computes one or more predicted device quantities based on the candidate geometry. In preferred embodiments, the force and power estimator 1308 computes Casimir pressure values for the candidate gaps, determines a directional pressure differential Delta_P, computes a net force from Delta_P and effective area, and estimates displacement, mechanical power, electrical power, voltage, current, or array-scaled output as appropriate to the embodiment. In some implementations, the force and power estimator 1308 also computes expected stack output, resonant response, threshold margins, or expected conditioning requirements.

The layout generator 1310 uses accepted geometric and structural outputs to generate a device layout. In some embodiments, the layout generator 1310 produces mask-ready MEMS geometry, multilayer layout geometry, array-routing geometry, patterned-surface geometry, or packaging information. In other embodiments, the layout generator 1310 produces a parameterized design representation that can later be converted into fabrication-ready forms. The fabrication package output 1316 may include one or more layout files, process parameters, material selections, stack definitions, routing definitions, device dimensions, or another manufacturing-oriented output package.

The proof or verification engine 1312 preserves an optional formal-support embodiment in which one or more properties of the candidate design are checked prior to fabrication or deployment. In preferred embodiments, the proof or verification engine 1312 checks directional positivity, phi-gap relations, scaling identities, or other formal properties associated with the disclosed architecture. In some embodiments, the proof or verification engine 1312 interacts with a formal proof environment to verify one or more results corresponding to the force-differential mechanism, the deterministic spacing family, or the structured mode-engineering family. In other embodiments, the proof or verification engine 1312 may perform rule-based validation, scripted checks, or computational certification short of full formal proof.

The acceptance-criteria evaluator 1314 applies one or more selection rules to determine whether a candidate design is accepted, modified, or rejected. In broad embodiments, the acceptance-criteria evaluator 1314 confirms that d_narrow is less than d_wide and that Delta_P is positive. In preferred embodiments, the acceptance-criteria evaluator 1314 further confirms that a target output threshold is met, that a selected cavity span belongs to a finite allowed set where required, that a recognition-length threshold rule is satisfied where required, or that a proof or verification check has passed where such checking is enabled. In some embodiments, the acceptance-criteria evaluator 1314 may rank multiple candidate designs according to force margin, fabrication tolerance, roughness tolerance, stage count, output level, or another design criterion.

The fabricated-device handoff 1318 represents transfer of accepted design outputs into a fabrication, assembly, packaging, or deployment pipeline. In some embodiments, the fabricated-device handoff 1318 is a handoff to a semiconductor foundry, MEMS fabrication line, nanofabrication workflow, or layered-assembly process. In other embodiments, the fabricated-device handoff 1318 is a handoff to a simulation-to-fabrication environment or other manufacturing process. The validation report 1320 may include selected gap values, phi-rung assignments, predicted force and power values, accepted span-selection results, threshold-filtering results, proof outcomes, or another structured record associated with the accepted design.

The FIG. 13 design workflow should be treated as a supporting and optional embodiment family rather than as the identity of the core invention. The core invention remains the unequal-gap directional Casimir harvester. However, FIG. 13 preserves valuable subject matter for design-medium claims, proof-assisted workflow claims, verification-based fabrication gating claims, and future continuation strategies directed to integrated computational design and validation.

In preferred formal-support embodiments, the present materials identify specific machine-verified modules and theorem families corresponding to the disclosed harvester architecture. These include a directional Casimir harvester module supporting casimir_pressure_positive, casimir_scaling, phi_gap_ratio, phi_gap_pos, stronger_narrow, net_casimir_positive, output_power_positive, and array_linear_scaling; a vacuum-fluctuation module supporting vacuum-energy positivity and eight-tick cancellation; an eight-tick foundation module supporting sum_8_phases_eq_zero; and additional structured-energy modules supporting operating-pressure positivity, extractable-work positivity, ledger-neutral operation, zero-imbalance safety, and phi-ratio optimality in preferred RS-native control families. These formal results provide an exact support layer for preferred embodiments and fallback claim positions.

In preferred worked examples, representative gap values, active areas, spring constants, and transducer efficiencies are used to compute force, displacement, and output for specific harvester configurations. In one representative MEMS embodiment, a narrow gap of approximately 50 nm and a wide gap of approximately 80.9 nm are used as a phi-related gap pair. In representative array embodiments, multiple cells are distributed over a common substrate and their outputs are combined. In representative stacked embodiments, repeated narrow-gap and wide-gap stages are vertically integrated and electrically combined in series to increase voltage. These worked numerical examples provide concrete implementation support for the unequal-gap core, the phi-scaled preferred family, and the array and stack scaling families.

The foregoing figures and embodiments illustrate that the present disclosure is organized around a stable core inventive mechanism and multiple subordinate embodiment families.

The stable core inventive mechanism is an asymmetric Casimir cavity having unequal opposed gaps that produce a directional pressure differential on a movable conductive element, with conversion of resulting motion into electrical output. A principal deterministic preferred embodiment family applies a phi-scaled spacing rule to the unequal-gap geometry. A further structured preferred embodiment family applies eight-tick span selection and recognition-length threshold filtering to shape cavity mode behavior. Additional families preserve MEMS implementations, patterned surfaces, arrays, stacks, control systems, proof-assisted design workflows, dynamic hybrid operation, spiral geometries, and downstream integrations.

In the present disclosure, load-bearing claim support is therefore provided at multiple levels. In the present disclosure, load-bearing claim support is therefore provided at multiple levels. A first claim track is supported by the unequal-gap directional-force architecture and its transduction pathway. A second claim track is supported by the angularly selective metamaterial architecture in which one cavity-facing plate suppresses selected vacuum modes relative to an opposing reflective plate and thereby produces a directional Casimir pressure differential. Additional fallback support is provided by phi-scaled spacing, patterned boundary structures, planar arrays, stacked multilayer architectures, transducer families, monitoring and control features, computational design workflows, and advanced modulated or non-planar embodiments. This layered disclosure structure is intended to preserve broad protection while maintaining priority-clean support for directional-harvesting embodiments expressly disclosed in the priority materials.

The present materials further identify formal support corresponding to positivity of Casimir pressure, Casimir scaling, phi-gap ratio and positivity, stronger narrow-side force, positive net directional differential, positive output-power formulation, linear array scaling, and eight-tick cancellation. The present materials further preserve exact analytical expressions for pressure, gap ordering, directional differential, allowed-mode counting, and energy-density differential in the preferred RS-native embodiments, as well as worked numerical implementation examples and fabrication-oriented embodiment detail. These formally supported, analytically specified, and numerically illustrated features strengthen the disclosure by providing exact support for preferred embodiments and fallback positions, while the detailed make-and-use disclosure provided herein supplies the practical structural and operational context for fabrication, operation, and claim support.

Although particular embodiments have been described in detail, the disclosed subject matter is not limited to the specific structures, dimensions, materials, process flows, transducer types, array topologies, control architectures, or advanced embodiment families expressly set forth herein. Variations, substitutions, combinations, staged implementations, and partial integrations may be employed so long as an operative directional Casimir harvesting mechanism is preserved, including unequal-gap asymmetry, anisotropic spectral admission produced by an angularly selective metamaterial, or combinations thereof. Accordingly, the detailed description should be understood as illustrative and enabling, while the scope of protection is defined by the claims that follow.

What is claimed is:

1. A method for directional harvesting of energy, comprising:
providing an asymmetric Casimir cavity including a movable conductive element positioned between a first boundary structure and a second boundary structure;
defining, by the movable conductive element and the first and second boundary structures, a first gap on a first side of the movable conductive element and a second gap on a second side of the movable conductive element, the first gap being smaller than the second gap;
generating, by the asymmetric Casimir cavity, a directional Casimir pressure differential across the movable conductive element such that a pressure associated with the first gap exceeds a pressure associated with the second gap;
displacing the movable conductive element in response to the directional Casimir pressure differential; and
converting the displacement of the movable conductive element into electrical output.

2. A method according to claim 1, wherein the first gap and the second gap satisfy:
d_wide/d_narrow=phi^Delta_r, where d_wide is the second gap, d_narrow is the first gap, Delta_r is an integer rung separation greater than or equal to 1, and phi=(1+sqrt(5))/2, and wherein d_narrow is between 10 nm and 500 nm and Delta_r is between 1 and 5.

3. A method according to claim 1, wherein converting the displacement into electrical output comprises applying strain associated with the displacement to a piezoelectric transducer.

4. A method according to claim 1, wherein converting the displacement into electrical output comprises coupling the displacement to a transducer selected from the group consisting of a piezoelectric transducer, a magnetostrictive transducer, an electromagnetic transducer, and an electrostatic transducer.

5. A method according to claim 1, further comprising restoring the movable conductive element toward a starting position with a restoring structure after the displacement.

6. A method according to claim 1, further comprising patterning at least one cavity-facing surface with a periodic surface topography configured to alter cavity mode behavior.

7. A method according to claim 6, wherein the periodic surface topography has a phi-related period defined by Lambda=Lambda_0*phi^r, where r is an integer.

8. A method according to claim 1, further comprising selecting a cavity span from a finite allowed set associated with eight-tick periodicity.

9. A method according to claim 1, further comprising applying a recognition-length threshold to suppress modes having wavelengths shorter than a recognition length lambda_rec.

10. A method according to claim 1, further comprising verifying net electrical generation by (i) measuring electrical output energy E_out delivered to a calibrated load or storage element over a time window and (ii) measuring total externally supplied input energy E_in to reset, bias, modulation, control, monitoring, calibration, or conditioning over the same time window, and accepting operation as exhibiting net generation when (E_out−E_in) is greater than or equal to a predefined positive margin.

11. A directional Casimir harvester system, comprising:
a first boundary structure;
a second boundary structure;
a movable conductive element positioned between the first boundary structure and the second boundary structure so as to define a first gap on a first side of the movable conductive element and a second gap on a second side of the movable conductive element, the first gap being smaller than the second gap;
a restoring structure coupled to the movable conductive element; and
a transducer coupled to the movable conductive element or the restoring structure and configured to convert motion of the movable conductive element caused by a directional Casimir pressure differential into electrical output.

12. A system according to claim 11, wherein the movable conductive element comprises a shuttle plate or a shuttle membrane.

13. A system according to claim 11, wherein the first gap and the second gap satisfy a phi-scaled relationship:
d_wide/d_narrow=phi^Delta_r, where Delta_r is an integer rung separation greater than or equal to 1 and phi=(1+sqrt(5))/2.

14. A system according to claim 11, wherein at least one cavity-facing surface includes a patterned region having a periodic topography configured to alter cavity mode behavior.

15. A system according to claim 11, further comprising a plurality of asymmetric Casimir harvester cells arranged in a planar array on a common substrate and electrically coupled to a common output bus.

16. A system according to claim 11, further comprising a stacked multilayer architecture including a plurality of vertically repeated asymmetric cavity stages electrically coupled to provide a combined output.

17. A system according to claim 11, further comprising a reference cavity or coherence monitor, and a watchdog circuit configured to disconnect or limit electrical coupling to the transducer when a monitored imbalance-related quantity exceeds a threshold, and an auto-calibration module configured to maintain a target gap relationship.

18. A directional Casimir harvester system, comprising: a first plate patterned with a metamaterial having an angular transmission cutoff alpha measured from a surface normal of the first plate such that electromagnetic vacuum modes incident at an incidence angle theta measured from the surface normal greater than alpha are suppressed; a second reflective plate spaced from the first plate by a gap g between 10 nm and 1 um, the second reflective plate lacking said metamaterial; and a transducer mechanically coupled to at least one of the first plate and the second reflective plate and configured to convert a net directional Casimir pressure differential into electrical output.

19. A system according to claim 18, wherein the transducer comprises a piezoelectric cantilever, and wherein the metamaterial comprises cylindrical scatterers arranged on a lattice over the first plate, the scatterers having a radius of approximately 0.25 g and a height of approximately 2 g, and having a lattice pitch of approximately (phi/pi)*g, where phi=(1+sqrt(5))/2.

20. A system according to claim 18, wherein the system forms part of a stacked array comprising a plurality of directional Casimir harvester systems electrically coupled to provide combined output.
